(19) United States
(12) Patent Application Publication
(10) Pub. No.: US 2021/0018840 A1
(43) Pub. Date: Jan. 21, 2021

(54) SILICON-CONTAINING RESIST UNDERLAYER FILM-FORMING COMPOSITION WHICH CONTAINS PROTECTED PHENOLIC GROUP AND NITRIC ACID

(71) Applicant: NISSAN CHEMICAL CORPORATION, Tokyo (JP)

(72) Inventors: Wataru SHIBAYAMA, Toyama-shi (JP); Satoshi TAKEDA, Toyama-shi (JP); Ken ISHIBASHI, Toyama-shi (JP); Makoto NAKAJIMA, Toyama-shi (JP)

(73) Assignee: NISSAN CHEMICAL CORPORATION, Tokyo (JP)

(21) Appl. No.: 16/981,801

(22) PCT Filed: Mar. 18, 2019
(86) PCT No.: PCT/JP2019/011245

§ 371 Date: Sep. 17, 2020

(30) Foreign Application Priority Data
Mar. 19, 2018 (JP) 2018-051617

(51) Int. Cl. G03F 7/11; G03F 7/075; G03F 7/26; G03F 7/16

(52) U.S. Cl. CPC G03F 7/11; G03F 7/168; G03F 7/26; G03F 7/0757

(57) ABSTRACT

A resist underlayer film-forming composition for lithography can produce a semiconductor device; specifically, for forming a resist underlayer film that can be used as a hard mask. It includes a hydrolysis condensate (c) of a hydrolyzable silane (a) as a silane, nitric acid ions, and a solvent, wherein the hydrolyzable silane (a) contains a hydrolyzable silane of the following Formula (1):

R¹ₐR²_{b}Si(R³)_{4-(a+b)} Formula (1)

[wherein R¹ is an organic group of the following Formula (2):

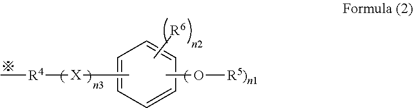

and is bonded to a silicon atom via an Si—C bond]. The composition may further include the hydrolyzable silane (a) and/or a hydrolysate (b) thereof. The amount of the nitric acid ions may fall within a range of 1 ppm to 1,000 ppm. In the hydrolysis condensate (c), the functional group of Formula (2) in the hydrolyzable silane of Formula (1) may satisfy a (hydrogen atom)/(hydrogen atom+R⁵ group) ratio by mole of 1% to 100%.

### TECHNICAL FIELD

The present invention relates to a composition for forming an underlayer film between a substrate and a resist (e.g., a photoresist or an electron beam resist) for use in the production of a semiconductor device. More particularly, the present invention relates to a resist underlayer film-forming composition for lithography for forming an underlayer film used as a layer under a photoresist in a lithography process for the production of a semiconductor device. Also, the present invention relates to a method for forming a resist pattern using the underlayer film-forming composition.

Fine processing by lithography using photoresists has been conventionally performed in the production of semiconductor devices. The fine processing is a processing method involving formation of a photoresist thin film on a semiconductor substrate (e.g., a silicon wafer); irradiation of the thin film with active rays (e.g., ultraviolet rays) through a mask pattern having a semiconductor device pattern drawn thereon; development of the irradiated thin film; and etching of the substrate with the resultant photoresist pattern serving as a protective film, to thereby form, on the surface of the substrate, fine irregularities corresponding to the pattern. In recent years, active rays having a shorter wavelength have tended to be used (i.e., shifting from KrF excimer laser (248 nm) to ArF excimer laser (193 nm)) in association with an increase in the degree of integration of semiconductor devices. This tendency causes a serious problem in terms of the influence of reflection of active rays from a semiconductor substrate.

A film known as a hard mask and containing a metal element (e.g., silicon or titanium) has been used as an underlayer film between a semiconductor substrate and a photoresist. In this case, the components of the photoresist significantly differ from those of the hard mask, and thus the rate of removal of these by dry etching greatly depends on the types of gas used for dry etching. The appropriate selection of a gas type enables the hard mask to be removed by dry etching without a large reduction in the thickness of the photoresist. Thus, in the recent production of semiconductor devices, a resist underlayer film has been disposed between a semiconductor substrate and a photoresist so as to achieve various effects, such as an antireflection effect. Although compositions for resist underlayer films have hitherto been studied, demand has arisen for development of a novel material for resist underlayer films because of, for example, various properties required for the films.

For example, there has been disclosed a resist underlayer film formed by application, on a semiconductor substrate, of a silicon-containing resist underlayer film-forming composition containing a phenyl group-containing chromophore, and baking of the composition in a lithographic process (see Patent Document 1).

For example, there has been disclosed a radiation-sensitive composition containing a polysiloxane exhibiting phenoplast crosslinking reactivity as a base resin (see Patent Document 2).

### PRIOR ART DOCUMENTS

### Patent Documents

Patent Document 1: International Publication WO 2015/194555 Pamphlet

Patent Document 2: International Publication WO 2016/199762 Pamphlet

### SUMMARY OF THE INVENTION

### Problems to be Solved by the Invention

A polysiloxane solution having high polarity may contain a large amount of ionic impurities. In some cases, the ionic impurities (e.g., polyvalent metal ions, or charged colloidal particles of such a metal or an oxide of the metal) are difficult to be removed with an ion exchange resin. In such a case, the polysiloxane solution may be subjected to filtration with a filter containing a polar group. However, the polar group-containing filter may cause problems, including an increase in the molecular weight of the polysiloxane through reaction between the polar group and a polysiloxane component, and occurrence of gelation. Although a volatile catalyst (e.g., hydrochloric acid) is removed in a solvent substitution process involving thermal treatment of the polysiloxane solution, a high-molecular-weight acid may be removed with the filter during filtration, and the polysiloxane becomes unstable when it passes through the filter.

In view of the above-described circumstances, an object of the present invention is to provide a resist underlayer film-forming composition for lithography that can be used in the production of a semiconductor device. Specifically, an object of the present invention is to provide a resist underlayer film-forming composition for lithography for forming a resist underlayer film that can be used as a hard mask.

Another object of the present invention is to provide a resist underlayer film-forming composition containing a polysiloxane that remains stable even after a step of filtering impurities with a filter.

### Means for Solving the Problems

The present inventors have conducted extensive studies for solving the aforementioned problems, and as a result have found that a polysiloxane solution containing a specific amount of nitric acid is stably filtered when the solution passes through a polar group-containing filter for removing ionic impurities. The present invention has been accomplished on the basis of this finding.

Accordingly, a first aspect of the present invention is a resist underlayer film-forming composition for lithography comprising a hydrolysis condensate (c) of a hydrolyzable silane (a) as a silane, nitric acid ions, and a solvent, wherein the hydrolyzable silane (a) contains a hydrolyzable silane of the following Formula (1):

R¹ₐR²_{b}Si(R³)₄-(a+b) Formula (1)

[wherein R¹ is an organic group of the following Formula (2):

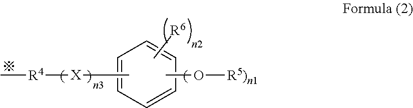

(wherein X is an oxygen atom, a sulfur atom, or a nitrogen atom; R⁴ is a single bond or a C₁₋₁₀ alkylene group; R⁵ is a C₁₋₁₀ alkyl group optionally containing a C₁₋₁₀ alkoxy group; R⁶ is a C₁₋₁₀ alkyl group; each of n1 and n2 satisfies 1≤n1≤5 and 0≤n2≤(5−n1); n3 is 0 or 1; and ※ is a site of bonding to a silicon atom) and is bonded to a silicon atom via an Si—C bond; R² is an alkyl group, an aryl group, a halogenated alkyl group, a halogenated aryl group, an alkoxyaryl group, an alkenyl group, or an organic group having an epoxy group, an acryloyl group, a methacryloyl group, a mercapto group, an amino group, or a cyano group, and is bonded to a silicon atom via an Si—C bond; R³ is an alkoxy group, an acyloxy group, or a halogen group; a is an integer of 1; b is an integer of 0 to 2; and a+b is an integer of 1 to 3].

A second aspect of the present invention is the resist underlayer film-forming composition according to the first aspect, wherein the composition further comprises the hydrolyzable silane (a) and/or a hydrolysate (b) thereof.

A third aspect of the present invention is the resist underlayer film-forming composition according to the first or second aspect, wherein the amount of the nitric acid ions contained in the composition falls within a range of 1 ppm to 1,000 ppm.

A fourth aspect of the present invention is the resist underlayer film-forming composition according to any one of the first to third aspects, wherein, in the hydrolysis condensate (c), the functional group of Formula (2) in the hydrolyzable silane of Formula (1) satisfies a (hydrogen atom)/(hydrogen atom+R⁵ group) ratio by mole of 1% to 100%.

A fifth aspect of the present invention is the resist underlayer film-forming composition according to any one of the first to fourth aspects, wherein the hydrolyzable silane (a) is a combination of the hydrolyzable silane of Formula (1) and an additional hydrolyzable silane, and the additional hydrolyzable silane is at least one hydrolyzable silane selected from the group consisting of hydrolyzable silanes of the following Formula (3):

R⁷_{c}Si(R⁸)_{4-c} Formula (3)

(wherein R⁷ is an alkyl group, an aryl group, a halogenated alkyl group, a halogenated aryl group, an alkoxyaryl group, an alkenyl group, or an organic group having an epoxy group, an acryloyl group, a methacryloyl group, a mercapto group, or a cyano group, and is bonded to a silicon atom via an Si—C bond; R⁸ is an alkoxy group, an acyloxy group, or a halogen atom; and c is an integer of 0 to 3) and the following Formula (4):

[R⁹_{d}Si(R¹⁰)_{3-d}]₂Yₑ Formula (4)

(wherein R⁹ is an alkyl group and is bonded to a silicon atom via an Si—C bond; R¹⁰ is an alkoxy group, an acyloxy group, or a halogen group; Y is an alkylene group or an arylene group; d is an integer of 0 or 1; and e is an integer of 0 or 1).

A sixth aspect of the present invention is the resist underlayer film-forming composition according to the fifth aspect, wherein the composition comprises, as a polymer, a hydrolysis condensate of a hydrolyzable silane containing a combination of the hydrolyzable silane of Formula (1) according to the first aspect and the hydrolyzable silane of Formula (3) according to the fifth aspect.

A seventh aspect of the present invention is the resist underlayer film-forming composition according to any one of the first to sixth aspects, wherein the composition further comprises an additive selected from water, an acid, a photoacid generator, a surfactant, a metal oxide, or any combination of these.

An eighth aspect of the present invention is a method for producing the resist underlayer film-forming composition according to any one of the first to seventh aspects, the method comprising a step (A) of filtering, with a filter comprising a polar group-containing filter, a polymer solution containing the hydrolysis condensate (c) of the hydrolyzable silane, or the hydrolysis condensate (c) of the hydrolyzable silane and the hydrolyzable silane (a) and/or the hydrolysate (b) thereof, and nitric acid ions, and a solvent.

A ninth aspect of the present invention is the method for producing the resist underlayer film-forming composition according to the eighth aspect, wherein the polar group-containing filter is a nylon filter.

A tenth aspect of the present invention is the method for producing the resist underlayer film-forming composition according to the eighth or ninth aspect, wherein the method further comprises a step (B) of filtering, with a filter, a solution prepared by addition of the additive according to the seventh aspect to the polymer solution.

An eleventh aspect of the present invention is a method for producing a semiconductor device, the method comprising a step of applying, onto a semiconductor substrate, the resist underlayer film-forming composition according to any one of the first to seventh aspects, followed by baking the composition, to thereby form a resist underlayer film; a step of applying a resist composition onto the underlayer film to thereby form a resist layer; a step of exposing the resist layer to light; a step of developing the resist layer after the light exposure to thereby form a resist pattern; a step of etching the resist underlayer film with the resist pattern; and a step of processing the semiconductor substrate with the patterned resist layer and resist underlayer film.

A twelfth aspect of the present invention is a method for producing a semiconductor device, the method comprising a step of forming an organic underlayer film on a semiconductor substrate; a step of applying, onto the organic underlayer film, the resist underlayer film-forming composition according to any one of the first to seventh aspects, followed by baking the composition, to thereby form a resist underlayer film; a step of applying a resist composition onto the resist underlayer film to thereby form a resist layer; a step of exposing the resist layer to light; a step of developing the resist layer after the light exposure to thereby form a resist pattern; a step of etching the resist underlayer film with the resist pattern; a step of etching the organic underlayer film with the patterned resist underlayer film; and a step of processing the semiconductor substrate with the patterned organic underlayer film.

### Effects of the Invention

In the present invention, a resist underlayer film is formed by an application process on a substrate or on an organic underlayer film disposed on the substrate, and a resist film (e.g., a photoresist or electron beam resist film) is formed on the resist underlayer film. Subsequently, a resist pattern is formed by light exposure and development, and the resist underlayer film is dry-etched with the resist film having the resist pattern, to thereby transfer the pattern onto the resist underlayer film. The substrate is processed with the patterned resist underlayer film. Alternatively, the pattern is transferred onto the organic underlayer film by etching, and the substrate is processed with the organic underlayer film.

Formation of a fine pattern on a resist film tends to cause a reduction in the thickness of the resist film for preventing pattern collapse. In a dry etching process for transferring the pattern of the thinned resist film onto an underlayer film present below the resist film, the pattern cannot be transferred to the underlayer film if the etching rate of the underlayer film is not higher than that of the film above the underlayer film. In the present invention, a substrate is coated with the resist underlayer film of the invention (containing an inorganic silicon compound) with or without intervention of an organic underlayer film disposed on the substrate, and the resist underlayer film is coated with a resist film (organic resist film). The dry etching rate of an organic component film greatly differs from that of an inorganic component film depending on a selected etching gas. Specifically, the dry etching rate of an organic component film increases by using an oxygen-containing gas, whereas the dry etching rate of an inorganic component film increases by using a halogen-containing gas.

For example, a resist pattern is formed on the resist film, and the resist underlayer film of the invention present below the resist film is dry-etched with a halogen-containing gas, to thereby transfer the pattern onto the resist underlayer film. The substrate is processed with a halogen-containing gas by using the pattern-transferred resist underlayer film. Alternatively, the organic underlayer film below the pattern-transferred resist underlayer film is dry-etched with an oxygen-containing gas by using the resist underlayer film, to thereby transfer the pattern onto the organic underlayer film, and the substrate is processed with a halogen-containing gas by using the pattern-transferred organic underlayer film.

In recent years, thinning of a resist has been remarkable in leading-edge semiconductor devices, and a silicon-containing resist underlayer film has been required to have improved lithographic characteristics in a tri-layer process. In the present invention, a phenolic hydroxyl group or a hydroxyalkyl group contributes to an improvement in adhesion between a resist underlayer film and a resist above the underlayer film, resulting in formation of a good resist pattern and improvements in solvent resistance and developer resistance. When the resist above the underlayer film is developed with an alkaline developer, scum is effectively reduced during formation of holes. When the resist above the underlayer film is developed with an organic solvent, pattern collapse is effectively prevented during formation of lines.

The composition of the present invention contains a hydrolyzable silane having protected phenolic groups. When a polysiloxane is produced by hydrolysis and condensation of a hydrolyzable silane without protection of phenolic groups, the dehydration and condensation of phenolic hydroxyl groups occur simultaneously to form a gel-like structure. In order to avoid such a problem, a hydrolyzable silane having protected phenolic groups is subjected to hydrolysis and condensation. In the present invention, nitric acid is used as a catalyst for the hydrolysis.

Since the polysiloxane solution of the present invention contains nitric acid, the polysiloxane solution exhibits such an effect that it remains stable even after it is passed through a polar group-containing filter (e.g., a nylon filer) for removal of ionic impurities. The polysiloxane is prepared by condensation of a hydrolysate of a hydrolyzable silane. Nitric acid, which is a non-volatile acid and can pass through a nylon filter, is used as a hydrolysis catalyst.

### MODES FOR CARRYING OUT THE INVENTION

The present invention is directed to a resist underlayer film-forming composition for lithography comprising a hydrolysis condensate (c) of a hydrolyzable silane (a) as a silane, nitric acid ions, and a solvent, wherein the hydrolyzable silane (a) contains a hydrolyzable silane of Formula (1).

In Formula (1), R¹ is an organic group of Formula (2) and is bonded to a silicon atom via an Si—C bond; R² is an alkyl group, an aryl group, a halogenated alkyl group, a halogenated aryl group, an alkoxyaryl group, an alkenyl group, or an organic group having an epoxy group, an acryloyl group, a methacryloyl group, a mercapto group, an amino group, or a cyano group, and is bonded to a silicon atom via an Si—C bond; R³ is an alkoxy group, an acyloxy group, or a halogen group; a is an integer of 1, b is an integer of 0 to 2; and a+b is an integer of 1 to 3.

In Formula (2), X is an oxygen atom, a sulfur atom, or a nitrogen atom; R⁴ is a single bond or a C₁₋₁₀ alkylene group; R⁵ is a C1-10 alkyl group optionally containing a C₁₋₁₀ alkoxy group; R⁶ is a C₁₋₁₀ alkyl group; each of n1 and n2 satisfies 1≤n1≤5 and 0≤n2≤(5−n1); n3 is 0 or 1; and ※ is a site of bonding to a silicon atom.

In the present invention, the composition may further contain the hydrolyzable silane (a) and/or a hydrolysate (b) thereof.

The amount of the silane of Formula (1) contained in the entire silane may be 50% by mole or less, or 1 to 50% by mole, 3 to 50% by mole, 5 to 50% by mole, 7 to 50% by mole, or 7 to 40% by mole, or 7 to 35% by mole, or 7 to 30% by mole, or 7 to 20% by mole, or 10 to 50% by mole, or 10 to 45% by mole, or 10 to 40% by mole, or 10 to 35% by mole, or 10 to 30% by mole, or 7 to 20% by mole.

The resist underlayer film-forming composition of the present invention contains the hydrolyzable silane of Formula (1), or the hydrolyzable silane of Formula (1) and an additional hydrolyzable silane (e.g., a hydrolyzable silane of Formula (3)), a hydrolysate thereof, or a hydrolysis condensate thereof, and a solvent. The composition may contain, as optional components, an acid, water, an alcohol, a curing catalyst, an acid generator, another organic polymer, a light-absorbing compound, a metal oxide, and a surfactant.

The resist underlayer film-forming composition of the present invention has a solid content of, for example, 0.1% by mass to 50% by mass, or 0.1% by mass to 30% by mass, or 0.1% by mass to 25% by mass. The term “solid content” as used herein corresponds to the amount of all components of the resist underlayer film-forming composition, except for the amount of a solvent component.

The amounts of the hydrolyzable silane, the hydrolysate thereof, and the hydrolysis condensate thereof in the solid content is 20% by mass or more, for example, 50% by mass to 100% by mass, 60% by mass to 99% by mass, or 70% by mass to 99% by mass.

The aforementioned alkyl group is a linear or branched alkyl group having a carbon atom number of 1 to 10. Examples of the alkyl group include methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

The alkyl group may be a cyclic alkyl group. Examples of cyclic alkyl groups having a carbon atom number of 1 to 10 include cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group.

The alkylene group may be, for example, an alkylene group derived from any of the aforementioned alkyl groups. Examples of such an alkylene group include methylene group derived from methyl group, ethylene group derived from ethyl group, and propylene group derived from propyl group.

The alkenyl group is a C₂₋₁₀ alkenyl group, and examples thereof include ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group.

The aryl group is, for example, a C6-20 aryl group, and examples thereof include phenyl group, o-methylphenyl group, m-methylphenyl group, p-methylphenyl group, o-chlorophenyl group, m-chlorophenyl group, p-chlorophenyl group, o-fluorophenyl group, p-mercaptophenyl group, o-methoxyphenyl group, p-methoxyphenyl group, p-aminophenyl group, p-cyanophenyl group, a-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group, and 9-phenanthryl group.

Examples of the organic group having an epoxy group include glycidoxymethyl group, glycidoxyethyl group, glycidoxypropyl group, glycidoxybutyl group, and epoxycyclohexyl group.

Examples of the organic group having an acryloyl group include acryloylmethyl group, acryloylethyl group, and acryloylpropyl group.

Examples of the organic group having a methacryloyl group include methacryloylmethyl group, methacryloylethyl group, and methacryloylpropyl group.

Examples of the organic group having a mercapto group include ethylmercapto group, butylmercapto group, hexylmercapto group, and octylmercapto group.

Examples of the organic group having a cyano group include cyanoethyl group and cyanopropyl group.

The aforementioned C₁₋₁₀ alkoxy group is, for example, an alkoxy group having a linear, branched, or cyclic alkyl moiety having a carbon atom number of 1 to 10. Examples of the alkoxy group include methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, and 1-ethyl-2-methyl-n-propoxy group. Examples of the cyclic alkoxy group include cyclopropoxy group, cyclobutoxy group, 1-methyl-cyclopropoxy group, 2-methyl-cyclopropoxy group, cyclopentyloxy group, 1-methyl-cyclobutoxy group, 2-methyl-cyclobutoxy group, 3-methyl-cyclobutoxy group, 1,2-dimethyl-cyclopropoxy group, 2,3-dimethyl-cyclopropoxy group, 1-ethyl-cyclopropoxy group, 2-ethyl-cyclopropoxy group, cyclohexyloxy group, 1-methyl-cyclopentyloxy group, 2-methyl-cyclopentyloxy group, 3-methyl-cyclopentyloxy group, 1-ethyl-cyclobutoxy group, 2-ethyl-cyclobutoxy group, 3-ethyl-cyclobutoxy group, 1,2-dimethyl-cyclobutoxy group, 1,3-dimethyl-cyclobutoxy group, 2,2-dimethyl-cyclobutoxy group, 2,3-dimethyl-cyclobutoxy group, 2,4-dimethyl-cyclobutoxy group, 3,3-dimethyl-cyclobutoxy group, 1-n-propyl-cyclopropoxy group, 2-n-propyl-cyclopropoxy group, 1-i-propyl-cyclopropoxy group, 2-i-propyl-cyclopropoxy group, 1,2,2-trimethyl-cyclopropoxy group, 1,2,3-trimethyl-cyclopropoxy group, 2,2,3-trimethyl-cyclopropoxy group, 1-ethyl-2-methyl-cyclopropoxy group, 2-ethyl-1-methyl-cyclopropoxy group, 2-ethyl-2-methyl-cyclopropoxy group, and 2-ethyl-3-methyl-cyclopropoxy group.

Examples of the aforementioned C2-20 acyloxy group include methylcarbonyloxy group, ethylcarbonyloxy group, n-propylcarbonyloxy group, i-propylcarbonyloxy group, n-butylcarbonyloxy group, i-butylcarbonyloxy group, s-butylcarbonyloxy group, t-butylcarbonyloxy group, n-pentylcarbonyloxy group, 1-methyl-n-butylcarbonyloxy group, 2-methyl-n-butylcarbonyloxy group, 3-methyl-n-butylcarbonyloxy group, 1,1-dimethyl-n-propylcarbonyloxy group, 1,2-dimethyl-n-propylcarbonyloxy group, 2,2-dimethyl-n-propylcarbonyloxy group, 1-ethyl-n-propylcarbonyloxy group, n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, 1-ethyl-1-methyl-n-propylcarbonyloxy group, 1-ethyl-2-methyl-n-propylcarbonyloxy group, phenylcarbonyloxy group, and tosylcarbonyloxy group.

Examples of the aforementioned halogen atom include fluorine, chlorine, bromine, and iodine.

Examples of the hydrolyzable silane of Formula (1) are as follows.

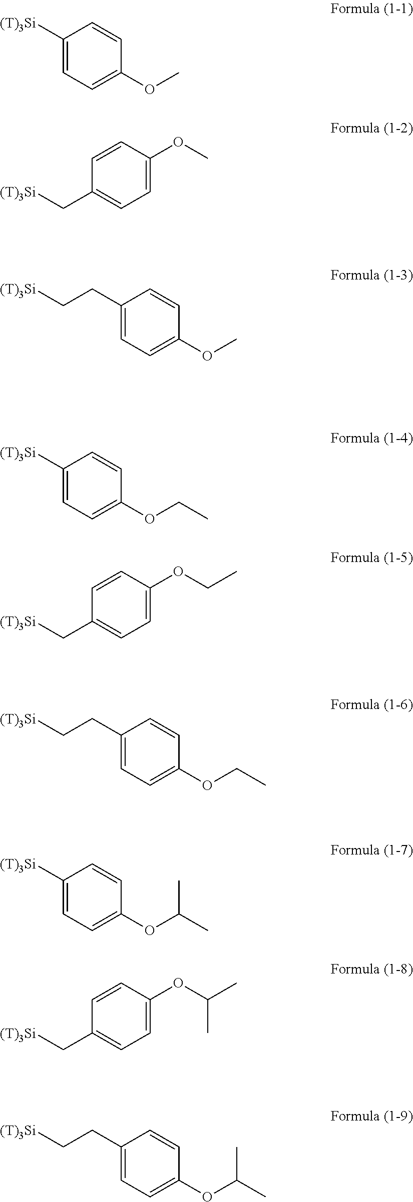

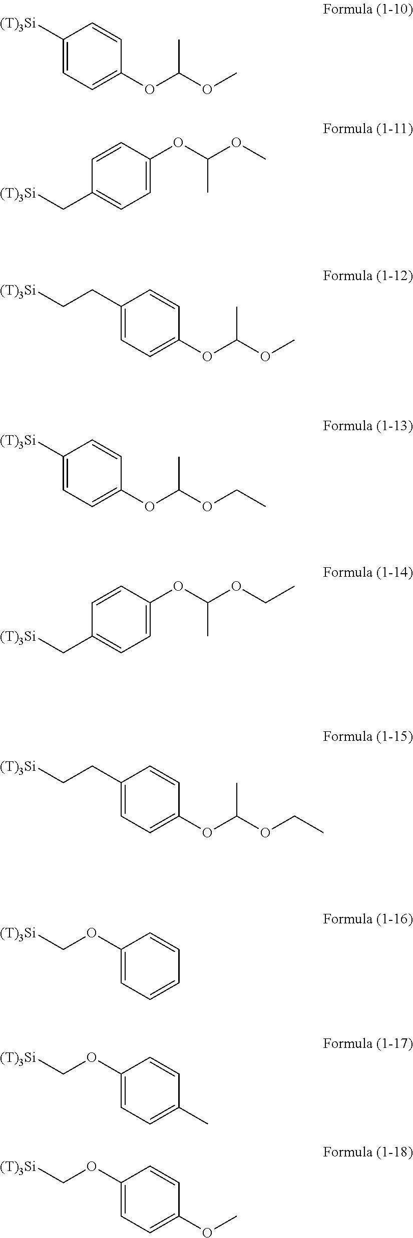

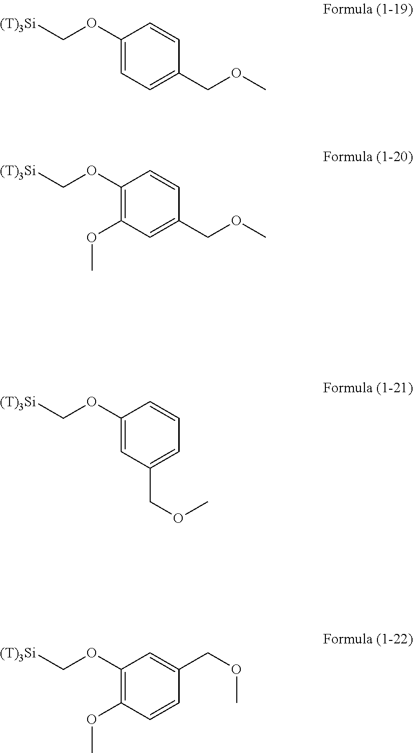

T in the aforementioned formulae is a hydrolyzable group that is an alkoxy group, an acyloxy group, or a halogen atom. The hydrolyzable group is preferably, for example, a methoxy group or an ethoxy group.

In the present invention, the hydrolyzable silane (a) is a combination of the hydrolyzable silane of Formula (1) and an additional hydrolyzable silane, and the additional hydrolyzable silane may be at least one hydrolyzable silane selected from the group consisting of hydrolyzable silanes of Formulae (3) and (4).

In Formula (3), R⁷ is an alkyl group, an aryl group, a halogenated alkyl group, a halogenated aryl group, an alkoxyaryl group, an alkenyl group, or an organic group having an epoxy group, an acryloyl group, a methacryloyl group, a mercapto group, or a cyano group, and is bonded to a silicon atom via an Si—C bond; R⁸ is an alkoxy group, an acyloxy group, or a halogen group; and c is an integer of 0 to 3.

In Formula (4), R⁹ is an alkyl group and is bonded to a silicon atom via an Si—C bond; R¹⁰ is an alkoxy group, an acyloxy group, or a halogen group; Y is an alkylene group or an arylene group; d is an integer of 0 or 1; and e is an integer of 0 or 1.

The above-exemplified groups can be applied to the alkyl group, aryl group, halogenated alkyl group, halogenated aryl group, alkenyl group, or organic group having an epoxy group, an acryloyl group, a methacryloyl group, a mercapto group, or a cyano group, alkoxy group, acyloxy group, or halogen group in Formulae (3) and (4).

Examples of the silicon-containing compound of Formula (3) include tetramethoxysilane, tetrachlorosilane, tetraacetoxysilane, tetraethoxysilane, tetra-n-propoxysilane, tetraisopropoxysilane, tetra-n-butoxysilane, methyltrimethoxysilane, methyltrichlorosilane, methyltriacetoxysilane, methyltripropoxysilane, methyltriacetoxysilane, methyltributoxysilane, methyltripropoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltrichlorosilane, vinyltriacetoxysilane, vinyltriethoxysilane, vinyltriacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, isopropoxyphenyltrimethoxysilane, isopropoxyphenyltriethoxysilane, isopropoxyphenyltriacetoxysilane, isopropoxyphenyltrichlorosilane, isopropoxybenzyltrimethoxysilane, isopropoxybenzyltriethoxysilane, isopropoxybenzyltriacetoxysilane, isopropoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, chloromethyltrimethoxysilane, chloromethyltriethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiethoxysilane, methylvinyldimethoxysilane, and methylvinyldiethoxysilane.

Examples of the silicon-containing compound of Formula (4) include methylenebistrimethoxysilane, methylenebistrichlorosilane, methylenebistriacetoxysilane, ethylenebistriethoxysilane, ethylenebistrichlorosilane, ethylenebistriacetoxysilane, propylenebistriethoxysilane, butylenebistrimethoxysilane, phenylenebistrimethoxysilane, phenylenebistriethoxysilane, phenylenebismethyldiethoxysilane, phenylenebismethyldimethoxysilane, naphthylenebistrimethoxysilane, bistrimethoxydisilane, bistriethoxydisilane, bisethyldiethoxydisilane, and bismethyldimethoxydisilane.

In the present invention, the hydrolyzable silane (a) may be a silane having a sulfone group or a silane having a sulfonamide group. Examples of these silanes are as follows.

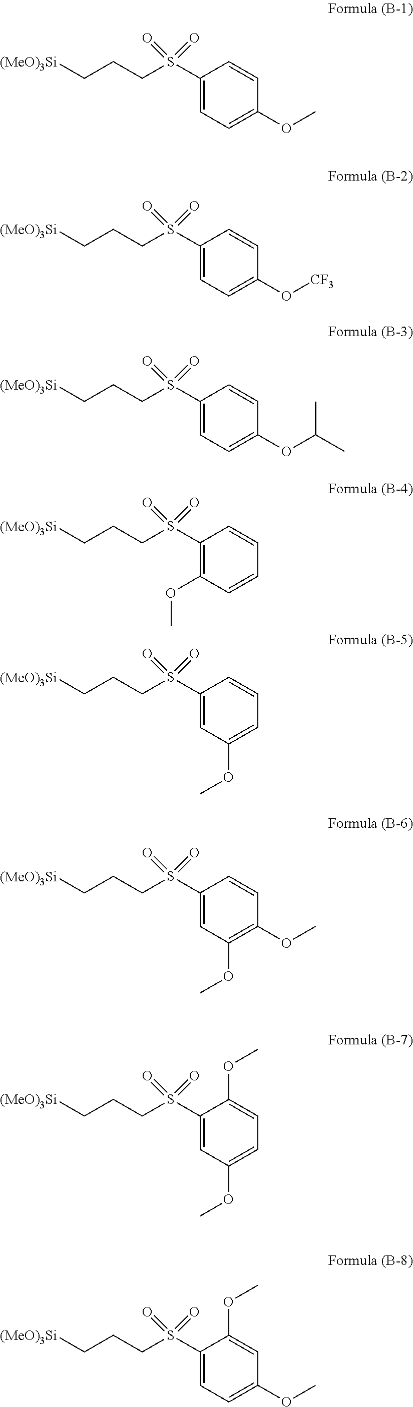

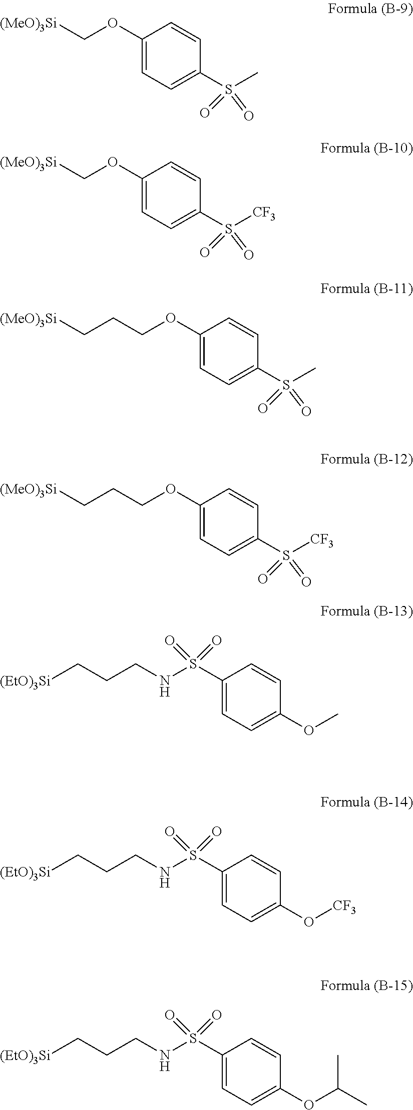

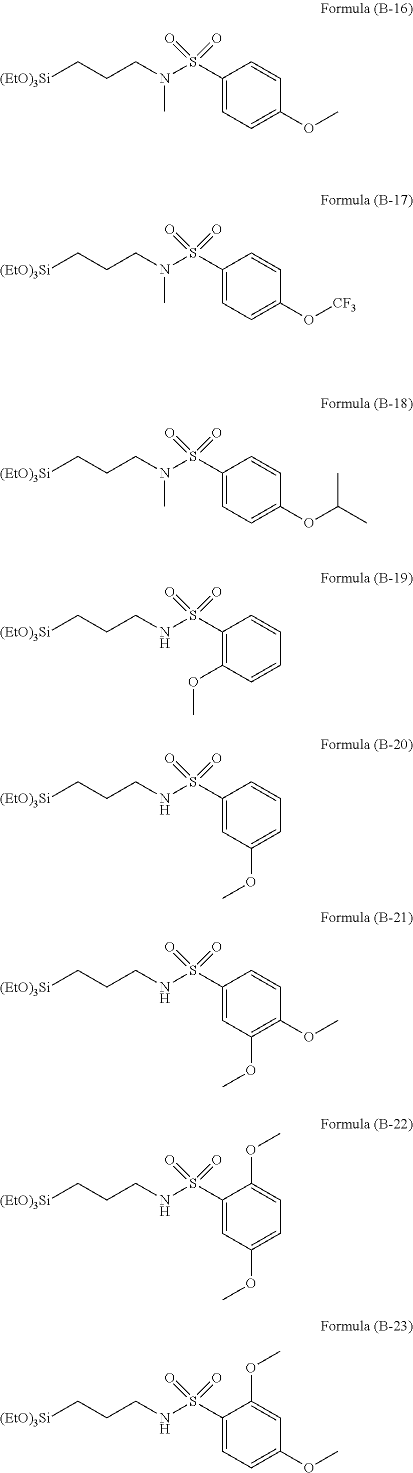

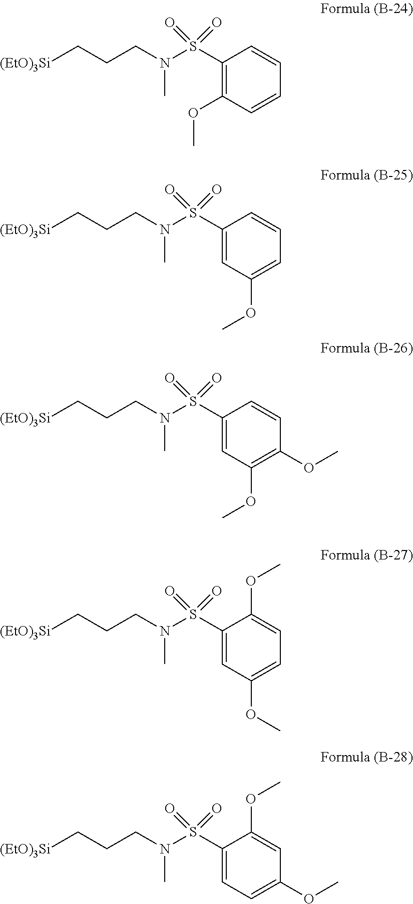

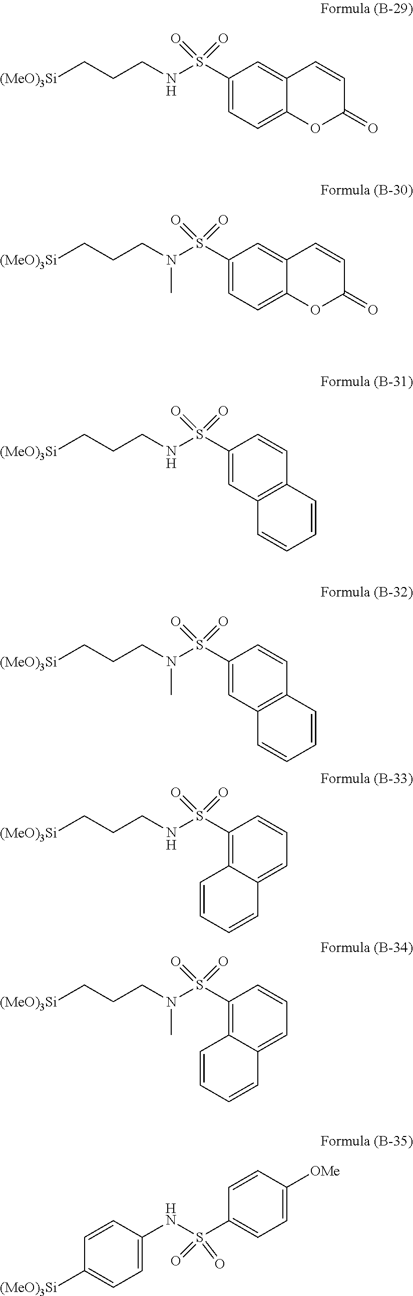

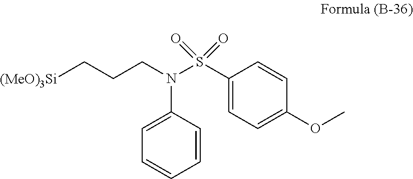

Specific examples of the hydrolysis condensate (polysiloxane) (c) used in the present invention are as follows.

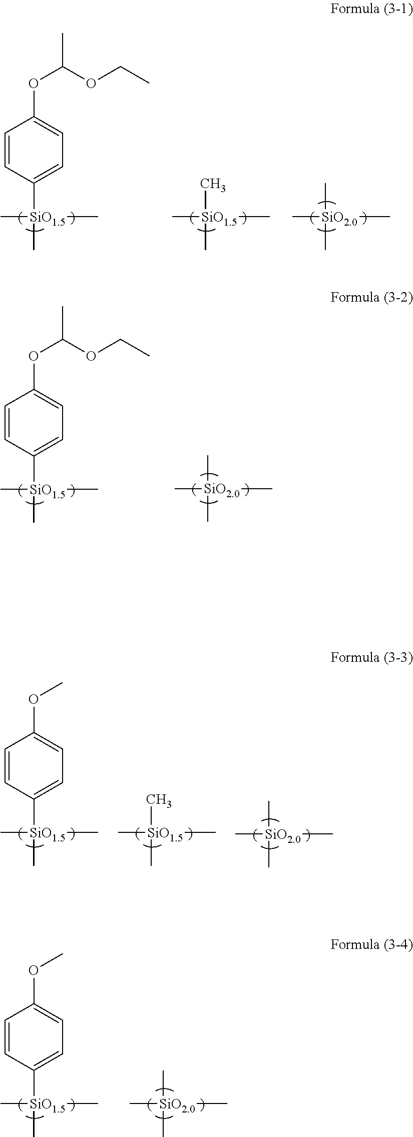

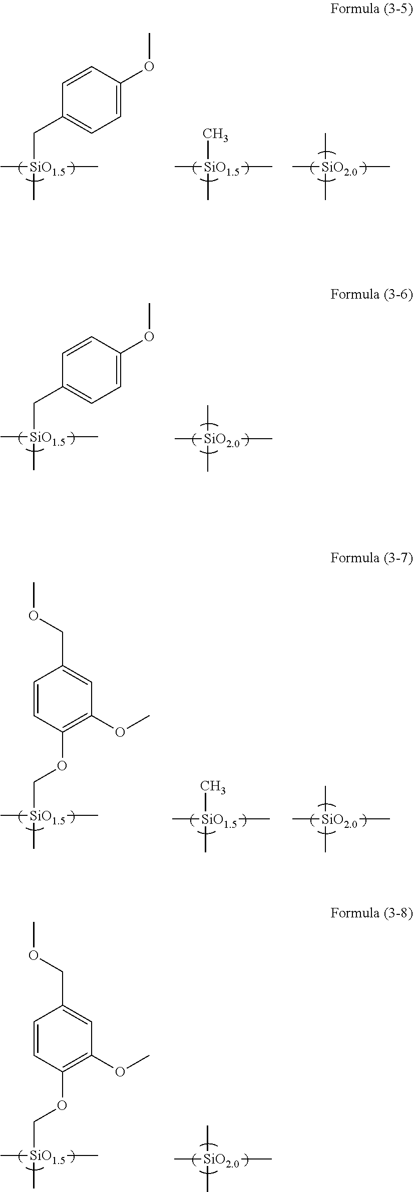

The hydrolysis condensate (polysiloxane) used in the present invention is produced by hydrolysis of a hydrolyzable silane in the presence of nitric acid serving as a hydrolysis catalyst. Hydrolysis and condensation of the hydrolyzable silane proceed first, and then reflux is performed. In this process, the protective group of phenol is eliminated in an amount of about 1% to 100% to thereby convert the protected phenol into phenol. In the hydrolysis condensate (c), the functional group of Formula (2) in the hydrolyzable silane of Formula (1) satisfies a (hydrogen atom)/(hydrogen atom+R⁵ group) ratio by mole of 1% to 100%.

The resist underlayer film-forming composition contains nitric acid ions derived from nitric acid in an amount of 1 ppm to 1,000 ppm. The hydrolysis condensate (polysiloxane) is converted into any of the following structures though elimination of the protective group of phenol.

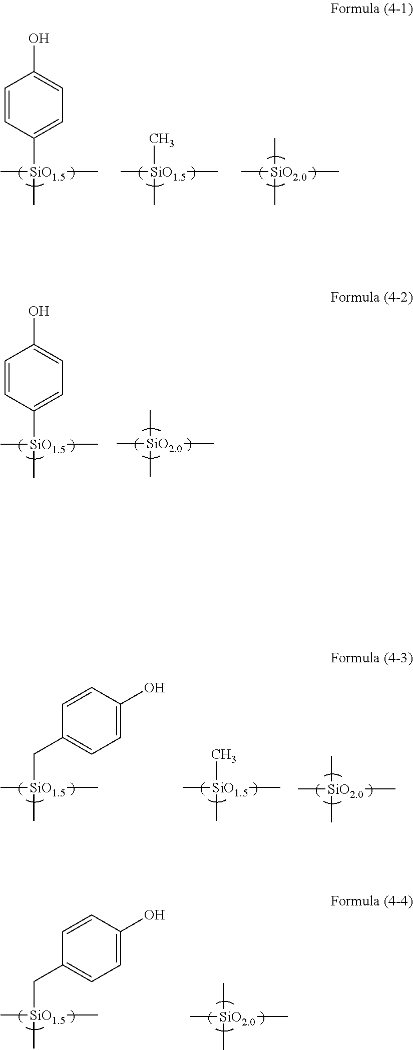

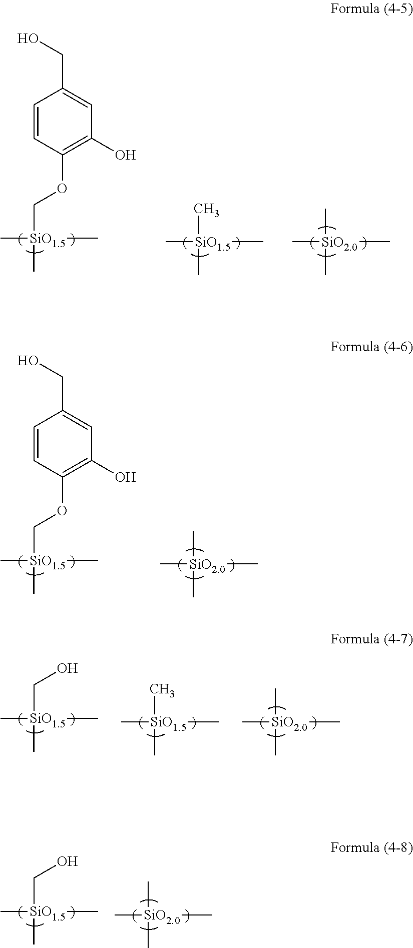

The hydrolysis condensate (polyorganosiloxane) (c) of the aforementioned hydrolyzable silane has a weight average molecular weight (Mw) of 1,000 to 1,000,000 or 1,000 to 100,000. The weight average molecular weight (Mw) is determined by GPC analysis in terms of polystyrene.

The GPC analysis can be performed under, for example, the following conditions: GPC apparatus (trade name: HLC-8220GPC, available from Tosoh Corporation), GPC columns (trade name: Shodex KF803L, KF802, and KF801, available from Showa Denko K.K.), a column temperature of 40° C., tetrahydrofuran serving as an eluent (elution solvent), a flow amount (flow rate) of 1.0 ml/min, and polystyrene (available from Showa Denko K.K.) as a standard sample.

For the hydrolysis of an alkoxysilyl group, an acyloxysilyl group, or a halogenated silyl group, 0.5 mol to 100 mol (preferably 1 mol to 10 mol) of water is used per mol of the hydrolyzable group.

Furthermore, 0.001 mol to 10 mol (preferably 0.001 mol to 1 mol) of a hydrolysis catalyst may be used per mol of the hydrolyzable group.

The reaction temperature for hydrolysis and condensation is generally 20° C. to 80° C.

The hydrolysis may be completely or partially performed. Thus, a hydrolysate or a monomer may remain in the resultant hydrolysis condensate.

A catalyst may be used for the hydrolysis and condensation. Nitric acid is used as a hydrolysis catalyst. Nitric acid may be used in combination with a metal chelate compound, an organic acid, an inorganic acid, an organic base, or an inorganic base.

Examples of the organic solvent used for the hydrolysis include aliphatic hydrocarbon solvents, such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon solvents, such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, and trimethylbenzene; monohydric alcohol solvents, such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol solvents, such as ethylene glycol, propylene glycol, 1,3-butylene glycol, pentanediol-2,4, 2-methylpentanediol-2,4, hexanediol-2,5, heptanediol-2,4,2-ethylhexanediol-1,3, diethylene glycol, dipropylene glycol, triethylene glycol, tripropylene glycol, and glycerin; ketone solvents, such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone; ether solvents, such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether, propylene glycol monoethyl ether, propylene glycol monopropyl ether, propylene glycol monobutyl ether, propylene glycol monomethyl ether acetate, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents, such as diethyl carbonate, methyl acetate, ethyl acetate, y-butyrolactone, y-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents, such as N-methylformamide, N,N-dimethylformamide, N,N-diethylformamide, acetamide, N-methylacetamide, N,N-dimethylacetamide, N-methylpropionamide, and N-methylpyrrolidone (NMP); and sulfur-containing solvents, such as dimethyl sulfide, diethyl sulfide, thiophene, tetrahydrothiophene, dimethyl sulfoxide, sulfolane, and 1,3-propanesultone. These solvents may be used alone or in combination of two or more species.

Particularly preferred are ketone solvents, such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone, in view of the preservation stability of the resultant solution.

In addition, bisphenol S or a bisphenol S derivative may be used as an additive. The amount of bisphenol S or a bisphenol S derivative is 0.01 parts by mass to 20 parts by mass, or 0.01 parts by mass to 10 parts by mass, or 0.01 parts by mass to 5 parts by mass relative to 100 parts by mass of the hydrolysis condensate (polyorganosiloxane) (c) of the aforementioned hydrolyzable silane.

Preferred examples of the bisphenol S or the bisphenol S derivative are as follows.

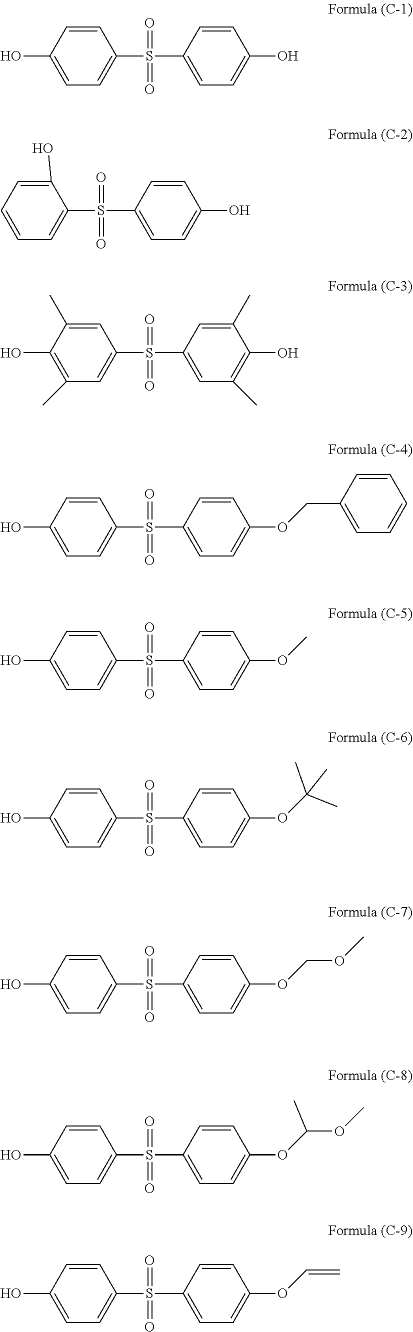

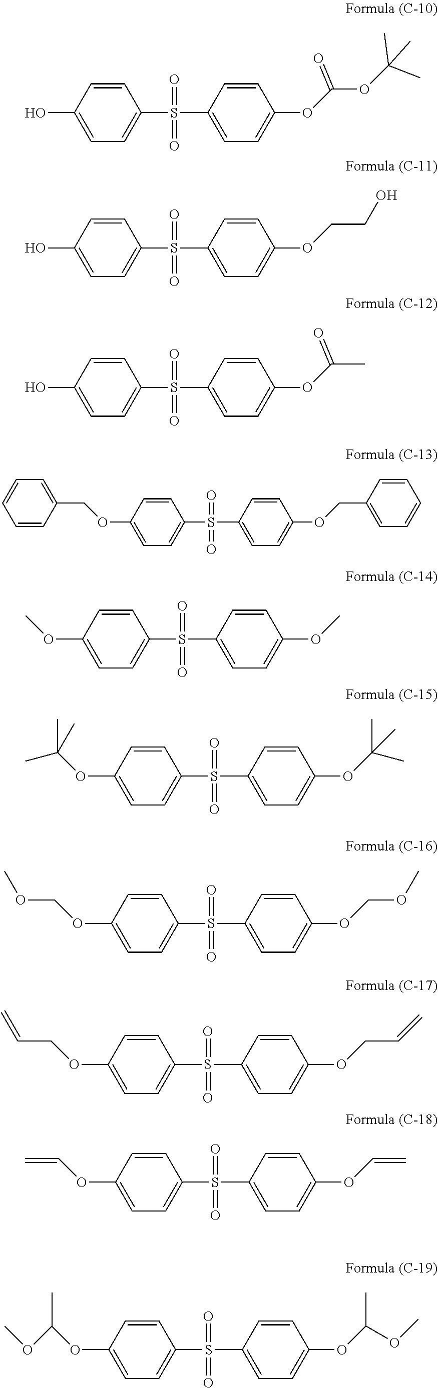

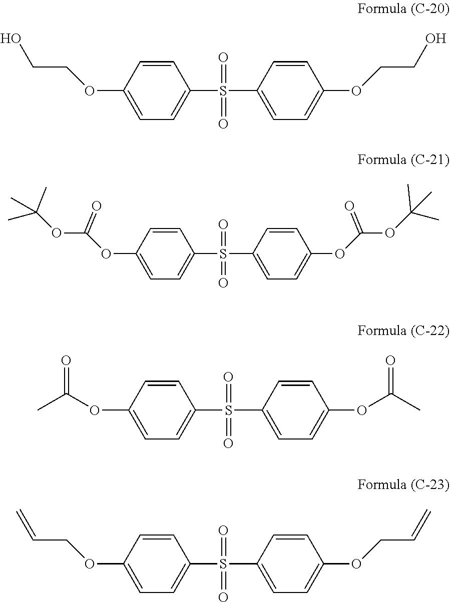

The resist underlayer film-forming composition of the present invention may contain a curing catalyst. The curing catalyst plays its own role during heating and curing of a coating film containing the polyorganosiloxane (c) composed of a hydrolysis condensate.

The curing catalyst may be an ammonium salt, a phosphine, a phosphonium salt, or a sulfonium salt.

Examples of the ammonium salt include:

a quaternary ammonium salt having a structure of the following Formula (D-1):

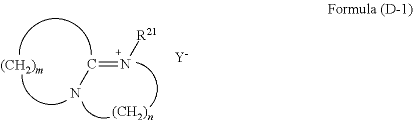

(wherein m is an integer of 2 to 11; n is an integer of 2 or 3; R²¹ is an alkyl group or an aryl group; and Y⁻ is an anion);

a quaternary ammonium salt having a structure of the following Formula (D-2):

R²²R²³R²⁴R²⁵N⁺Y⁻ Formula (D-2)

(wherein R²², R²³, R²⁴, and R²⁵ are each an alkyl group or an aryl group; N is a nitrogen atom; Y⁻ is an anion; and each of R²², R²³, R²⁴, and R²⁵ is bonded to the nitrogen atom via a C—N bond);

a quaternary ammonium salt having a structure of the following Formula (D-3):

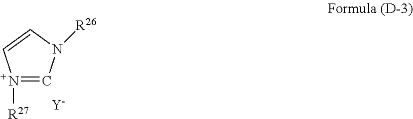

(wherein R²⁶ and R²⁷ are each an alkyl group or an aryl group; and Y⁻ is an anion);

a quaternary ammonium salt having a structure of the following Formula (D-4):

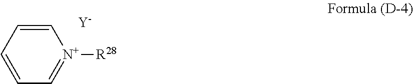

(wherein R²⁸ is an alkyl group or an aryl group; and Y⁻ is an anion);

a quaternary ammonium salt having a structure of the following Formula (D-5):

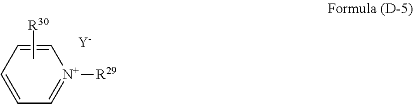

(wherein R²⁹ and R³⁰ are each an alkyl group or an aryl group; and Y⁻ is an anion); and

a tertiary ammonium salt having a structure of the following Formula (D-6):

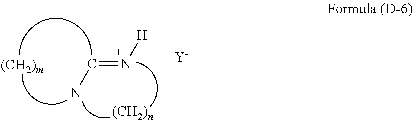

(wherein m is an integer of 2 to 11; n is an integer of 2 or 3; H is a hydrogen atom; and Y⁻ is an anion).

Examples of the phosphonium salt include a quaternary phosphonium salt of the following Formula (D-7):

R³¹R³²R³³R³⁴P⁺Y⁻ Formula (D-7)

(wherein R³¹, R³², R³³, and R³⁴ are each an alkyl group or an aryl group; P is a phosphorus atom; Y⁻ is an anion; and each of R³¹, R³², R³³, and R³⁴ is bonded to the phosphorus atom via a C—P bond).

Examples of the sulfonium salt include a tertiary sulfonium salt of the following Formula (D-8):

R³⁵R³⁶R³⁷S⁺Y⁻ Formula (D-8)

(wherein R³⁵, R³⁶, and R³⁷ are each an alkyl group or an aryl group; S is a sulfur atom; Y⁻ is an anion; and each of R³⁵, R³⁶, and R³⁷ is bonded to the sulfur atom via a C—S bond).

The compound of Formula (D-1) is a quaternary ammonium salt derived from an amine. In Formula (D-1), m is an integer of 2 to 11, and n is an integer of 2 or 3. R²¹ of the quaternary ammonium salt is a C₁₋₁₈ alkyl or aryl group, preferably a C₂₋₁₀ alkyl or aryl group. Examples of R²¹ include linear alkyl groups, such as ethyl group, propyl group, and butyl group, benzyl group, cyclohexyl group, cyclohexylmethyl group, and dicyclopentadienyl group. Examples of the anion (Y⁻) include halide ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻).

The compound of Formula (D-2) is a quaternary ammonium salt having a structure of R²²R²³R²⁴R²⁵N⁺Y⁻. R²², R²³, R²⁴, and R²⁵ of the quaternary ammonium salt are each a C₁₋₁₈ alkyl or aryl group, or a silane compound bonded to a silicon atom via an Si—C bond. Examples of the anion (Y⁻) include halide ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻). The quaternary ammonium salt is commercially available, and examples of the quaternary ammonium salt include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) is a quaternary ammonium salt derived from 1-substituted imidazole. In Formula (D-3), R²⁶ and R²⁷ are each a C₁₋₁₈ alkyl or aryl group, and the total number of carbon atoms of R²⁶ and R²⁷ is preferably 7 or more. Examples of R²⁶ include methyl group, ethyl group, propyl group, phenyl group, and benzyl group. Examples of R²⁷ include benzyl group, octyl group, and octadecyl group. Examples of the anion (Y⁻) include halide ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻). Although this compound is commercially available, the compound can be produced through, for example, reaction between an imidazole compound (e.g., 1-methylimidazole or 1-benzylimidazole) and an alkyl or aryl halide (e.g., benzyl bromide or methyl bromide).

The compound of Formula (D-4) is a quaternary ammonium salt derived from pyridine. In Formula (D-4), R²⁸ is a C₁₋₁₈ alkyl or aryl group, preferably a C₄₋₁₈ alkyl or aryl group. Examples of R²⁸ include butyl group, octyl group, benzyl group, and lauryl group. Examples of the anion (Y⁻) include halide ions, such as chloride ion (Cl⁻), bromide ion (Br), and iodide ion (I); and acid groups, such as carboxylate (—COO⁻), sulfonate (—SO₃⁻), and alcoholate (—O⁻). Although this compound is commercially available, the compound can be produced through, for example, reaction between pyridine and an alkyl or aryl halide, such as lauryl chloride, benzyl chloride, benzyl bromide, methyl bromide, or octyl bromide. Examples of this compound include N-laurylpyridinium chloride and N-benzylpyridinium bromide.

The compound of Formula (D-5) is a quaternary ammonium salt derived from a substituted pyridine, such as picoline. In Formula (D-5), R²⁹ is a C₁₋₁₈ alkyl or aryl group, preferably a C₄₋₁₈ alkyl or aryl group. Examples of R²⁹ include methyl group, octyl group, lauryl group, and benzyl group. R³⁰ is a C₁₋₁₈ alkyl or aryl group, and, for example, R³⁰ is a methyl group when the compound is a quaternary ammonium salt derived from picoline. Examples of the anion (Y⁻) include halide ions, such as chloride ion (Cl⁻), bromide ion (Br), and iodide ion (I); and acid groups, such as carboxylate (—COO⁻), sulfonate (—SO₃⁻), and alcoholate (—O⁻). Although this compound is commercially available, the compound can be produced through, for example, reaction between a substituted pyridine (e.g., picoline) and an alkyl or aryl halide, such as methyl bromide, octyl bromide, lauryl chloride, benzyl chloride, or benzyl bromide. Examples of this compound include N-benzylpicolinium chloride, N-benzylpicolinium bromide, and N-laurylpicolinium chloride.

The compound of Formula (D-6) is a tertiary ammonium salt derived from an amine. In Formula (D-6), m is an integer of 2 to 11, and n is an integer of 2 or 3. Examples of the anion (Y⁻) include halogen ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻). The compound can be produced through, for example, reaction between an amine and a weak acid, such as a carboxylic acid or phenol. Examples of the carboxylic acid include formic acid and acetic acid. When formic acid is used, the anion (Y⁻) is (HCOO⁻). When acetic acid is used, the anion (Y⁻) is (CH₃COO⁻). When phenol is used, the anion (Y⁻) is (C₆H₅O⁻).

The compound of Formula (D-7) is a quaternary phosphonium salt having a structure of R³¹R³²R³³R³⁴P⁺Y⁻. R³¹, R³², R³³, and R³⁴ are each a C₁₋₁₈ alkyl or aryl group, or a silane compound bonded to a silicon atom via an Si—C bond. Three of the four substituents R³¹ to R³⁴ are preferably a phenyl group or a substituted phenyl group, such as a phenyl group or a tolyl group. The remaining one substituent is a C₁₋₁₈ alkyl or aryl group, or a silane compound bonded to a silicon atom via an Si—C bond. Examples of the anion (Y⁻) include halide ions, such as chloride ion (Cl⁻), bromide ion (Br⁻), and iodide ion (I⁻); and acid groups, such as carboxylate (—COO⁻), sulfonate (—SO₃⁻), and alcoholate (—O⁻). This compound is commercially available, and examples of the compound include tetraalkylphosphonium halides, such as tetra-n-butylphosphonium halides and tetra-n-propylphosphonium halides; trialkylbenzylphosphonium halides, such as triethylbenzylphosphonium halides; triphenylmonoalkylphosphonium halides, such as triphenylmethylphosphonium halides and triphenylethylphosphonium halides; triphenylbenzylphosphonium halides; tetraphenylphosphonium halides; tritolylmonoarylphosphonium halides; and tritolylmonoalkylphosphonium halides (wherein the halogen atom is a chlorine atom or a bromine atom). Particularly preferred are triphenylmonoalkylphosphonium halides, such as triphenylmethylphosphonium halides and triphenylethylphosphonium halides; triphenylmonoarylphosphonium halides, such as triphenylbenzylphosphonium halides; tritolylmonoarylphosphonium halides, such as tritolylmonophenylphosphonium halides; and tritolylmonoalkylphosphonium halides, such as tritolylmonomethylphosphonium halides (wherein the halogen atom is a chlorine atom or a bromine atom).

Examples of the phosphine include primary phosphines, such as methylphosphine, ethylphosphine, propylphosphine, isopropylphosphine, isobutylphosphine, and phenylphosphine; secondary phosphines, such as dimethylphosphine, diethylphosphine, diisopropylphosphine, diisoamylphosphine, and diphenylphosphine; and tertiary phosphines, such as trimethylphosphine, triethylphosphine, triphenylphosphine, methyldiphenylphosphine, and dimethylphenylphosphine.

The compound of Formula (D-8) is a tertiary sulfonium salt having a structure of R³⁵R³⁶R³⁷S⁺Y⁻. R³⁵, R³⁶, and R³⁷ are each a C₁₋₁₈ alkyl or aryl group, or a silane compound bonded to a silicon atom via an Si—C bond. Two of the three substituents R³⁵ to R³⁷ are preferably a phenyl group or a substituted phenyl group, such as a phenyl group or a tolyl group. The remaining one substituent is a C₁₋₁₈ alkyl or aryl group. Examples of the anion (Y⁻) include halide ions, such as chloride ion (Cl⁻), bromide ion (Br⁻), and iodide ion (I⁻); and acid groups, such as carboxylate (—COO⁻), sulfonate (—SO₃⁻), alcoholate maleate anion, and nitrate anion. This compound is commercially available, and examples of the compound include trialkylsulfonium halides, such as tri-n-butylsulfonium halides and tri-n-propylsulfonium halides; trialkylbenzylsulfonium halides, such as diethylbenzylsulfonium halides; diphenylmonoalkylsulfonium halides, such as diphenylmethylsulfonium halides and diphenylethylsulfonium halides; triphenylsulfonium halides (wherein the halogen atom is a chlorine atom or a bromine atom); trialkylsulfonium carboxylates, such as tri-n-butylsulfonium carboxylate and tri-n-propylsulfonium carboxylate; trialkylbenzylsulfonium carboxylates, such as diethylbenzylsulfonium carboxylate; diphenylmonoalkylsulfonium carboxylates, such as diphenylmethylsulfonium carboxylate and diphenylethylsulfonium carboxylate; and triphenylsulfonium carboxylate. Triphenylsulfonium halides and triphenylsulfonium carboxylates are preferably used.

The composition of the present invention may contain a nitrogen-containing silane compound as a curing catalyst. Examples of the nitrogen-containing silane compound include imidazole ring-containing silane compounds, such as N-(3-triethoxysilypropyl)-4,5-dihydroimidazole.

The amount of the curing catalyst is 0.01 parts by mass to 10 parts by mass, or 0.01 parts by mass to 5 parts by mass, or 0.01 parts by mass to 3 parts by mass relative to 100 parts by mass of the hydrolysis condensate (polyorganosiloxane) (c) of the aforementioned hydrolyzable silane.

From a hydrolysis condensate (polymer) prepared by hydrolysis and condensation of a hydrolyzable silane with a catalyst in a solvent, alcohols (i.e., by-products) and water can be simultaneously removed by, for example, distillation under reduced pressure. In the case of the resist underlayer film-forming composition for lithography of the present invention, an organic acid, water, an alcohol, or a combination thereof may be added to the resist underlayer film-forming composition containing the hydrolysis condensate for stabilization of the composition.

Examples of the aforementioned organic acid include oxalic acid, malonic acid, methylmalonic acid, succinic acid, maleic acid, malic acid, tartaric acid, phthalic acid, citric acid, glutaric acid, citric acid, lactic acid, and salicylic acid. Of these, oxalic acid, maleic acid, etc. are preferred. The amount of the organic acid added is 0.1 parts by mass to 5.0 parts by mass relative to 100 parts by mass of the hydrolysis condensate (polyorganosiloxane) (c) of the aforementioned hydrolyzable silane. For example, pure water, ultrapure water, or ion-exchange water may be added to the composition, and the amount of the water added may be 1 part by mass to 20 parts by mass relative to 100 parts by mass of the resist underlayer film-forming composition.

The alcohol added to the composition is preferably an alcohol that easily dissipates by heating after the application of the composition. Examples of the alcohol include methanol, ethanol, propanol, isopropanol, and butanol. The amount of the alcohol added may be 1 part by mass to 20 parts by mass relative to 100 parts by mass of the resist underlayer film-forming composition.

The underlayer film-forming composition for lithography of the present invention may optionally contain, besides the aforementioned components, an organic polymer compound, a photoacid generator, and a surfactant.

The use of an organic polymer compound enables adjustment of, for example, the dry etching rate (the amount of a reduction in film thickness per unit time), attenuation coefficient, and refractive index of a resist underlayer film formed from the underlayer film-forming composition for lithography of the present invention.

No particular limitation is imposed on the organic polymer compound, and a variety of organic polymers may be used. For example, a polycondensation polymer and an addition polymerization polymer may be used. Examples of the usable addition polymerization polymer and polycondensation polymer include polyester, polystyrene, polyimide, acrylic polymer, methacrylic polymer, polyvinyl ether, phenol novolac, naphthol novolac, polyether, polyamide, and polycarbonate. Preferred is an organic polymer having an aromatic ring structure that functions as a light-absorbing moiety, such as a benzene ring, a naphthalene ring, an anthracene ring, a triazine ring, a quinoline ring, and a quinoxaline ring.

The organic polymer compound may be a polymer compound having a weight average molecular weight (Mw) of, for example, 1,000 to 1,000,000, or 3,000 to 300,000, or 5,000 to 200,000, or 10,000 to 100,000.

When the organic polymer compound is used, the amount thereof is 1 part by mass to 200 parts by mass, or 5 parts by mass to 100 parts by mass, or 10 parts by mass to 50 parts by mass, or 20 parts by mass to 30 parts by mass relative to 100 parts by mass of the hydrolysis condensate (polyorganosiloxane) (c) of the aforementioned hydrolyzable silane.

The resist underlayer film-forming composition of the present invention may contain an acid generator.

Examples of the acid generator include a thermal acid generator and a photoacid generator.

A photoacid generator generates an acid during the exposure of a resist. Thus, the acidity of an underlayer film can be adjusted. This is one method for adjusting the acidity of an underlayer film to the acidity of a resist serving as an upper layer of the underlayer film. Furthermore, the adjustment of the acidity of an underlayer film enables the control of the pattern shape of a resist formed as an upper layer of the underlayer film.

Examples of the photoacid generator contained in the resist underlayer film-forming composition of the present invention include an onium salt compound, a sulfonimide compound, and a disulfonyldiazomethane compound.

Examples of the onium salt compound include iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

A single photoacid generator may be used alone, or two or more photoacid generators may be used in combination.

When the photoacid generator is used, the amount thereof is 0.01 parts by mass to 5 parts by mass, or 0.1 parts by mass to 3 parts by mass, or 0.5 parts by mass to 1 part by mass relative to 100 parts by mass of the hydrolysis condensate (polyorganosiloxane) (c) of the aforementioned hydrolyzable silane.

As described above in paragraph [0022], the resist underlayer film-forming composition of the present invention may contain, as optional components, an acid, water, an alcohol, a curing catalyst, an acid generator, another organic polymer, a light-absorbing compound, a metal oxide, and a surfactant.

The amount of the metal oxide added to the composition may be 0.001 parts by mass to 100 parts by mass relative to 100 parts by mass of the hydrolysis condensate (polyorganosiloxane) (c) of the aforementioned hydrolyzable silane.

Examples of the metal oxide or partial metal oxide added to the composition include a hydrolysis condensate containing TiOx (titanium oxide, x=1 to 2), a hydrolysis condensate containing WOx (tungsten oxide, x=1 to 3), a hydrolysis condensate containing HfOx (hafnium oxide, x=1 to 2), a hydrolysis condensate containing ZrOx (zirconium oxide, x=1 to 2), a hydrolysis condensate containing AlOx (aluminum oxide, x=1 to 1.5), metatungstic acid, ammonium metatungstate, silicotungstic acid, ammonium silicotungstate, molybdic acid, ammonium molybdate, phosphomolybdic acid, and ammonium phosphomolybdate. The amount of the metal oxide added may be 0.001 parts by mass to 100 parts by mass relative to 100 parts by mass of the composition applied to a resist pattern. The metal oxide or the partial metal oxide can be prepared in the form of a hydrolysis condensate of a metal alkoxide. The partial metal oxide may contain an alkoxide group.

A surfactant effectively prevents formation of, for example, pinholes and striations during application of the resist underlayer film-forming composition for lithography of the present invention to a substrate.

Examples of the surfactant contained in the resist underlayer film-forming composition of the present invention include nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylallyl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-containing surfactants, such as trade names EFTOP EF301, EF303, and EF352 (available from Tohkem Products Corporation), trade names MEGAFAC F171, F173, R-08, R-30, R-30N, and R-40LM (available from DIC Corporation), Fluorad FC430 and FC431 (available from Sumitomo 3M Limited), trade name Asahi Guard AG710 and trade names SURFLON S-382, SC101, SC102, SC103, SC104, SC105, and SC106 (available from Asahi Glass Co., Ltd.); and Organosiloxane Polymer KP341 (available from Shin-Etsu Chemical Co., Ltd.). These surfactants may be used alone or in combination of two or more species. When the surfactant is used, the amount thereof is 0.0001 parts by mass to 5 parts by mass, or 0.001 parts by mass to 1 part by mass, or 0.01 parts by mass to 1 part by mass relative to 100 parts by mass of the hydrolysis condensate (polyorganosiloxane) (c) of the aforementioned hydrolyzable silane.

The resist underlayer film-forming composition of the present invention may also contain, for example, a rheology controlling agent and an adhesion aid. A rheology controlling agent is effective for improving the fluidity of the underlayer film-forming composition. An adhesion aid is effective for improving the adhesion between a semiconductor substrate or a resist and an underlayer film.

No particular limitation is imposed on the solvent used in the resist underlayer film-forming composition of the present invention, so long as the solvent can dissolve the aforementioned solid component. Examples of such a solvent include methylcellosolve acetate, ethylcellosolve acetate, propylene glycol, propylene glycol monomethyl ether, propylene glycol monoethyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropinoate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol mooethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methybutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol, and y-butyrolactone. These solvents may be used alone or in combination of two or more species.

Next will be described the use of the resist underlayer film-forming composition of the present invention.

The resist underlayer film-forming composition of the present invention is applied onto a substrate used for the production of a semiconductor device (e.g., a silicon wafer substrate, a silicon/silicon dioxide-coated substrate, a silicon nitride substrate, a glass substrate, an ITO substrate, a polyimide substrate, or a substrate coated with a low dielectric constant material (low-k material)) by an appropriate application method with, for example, a spinner or a coater, followed by baking of the composition, to thereby form a resist underlayer film. The baking is performed under appropriately determined conditions; i.e., a baking temperature of 80° C. to 250° C. and a baking time of 0.3 minutes to 60 minutes. Preferably, the baking temperature is 150° C. to 250° C., and the baking time is 0.5 minutes to 2 minutes. The thickness of the thus-formed underlayer film is, for example, 10 nm to 1,000 nm, or 20 nm to 500 nm, or 50 nm to 300 nm, or 100 nm to 200 nm.

Subsequently, for example, a photoresist layer is formed on the resist underlayer film. The photoresist layer can be formed by a well-known process; i.e., application of a photoresist composition solution onto the underlayer film, and baking of the composition. The thickness of the photoresist layer is, for example, 50 nm to 10,000 nm, or 100 nm to 2,000 nm, or 200 nm to 1,000 nm.

In the present invention, an organic underlayer film can be formed on a substrate, the resist underlayer film of the present invention can then be formed on the organic underlayer film, and then the resist underlayer film can be coated with a photoresist. This process can narrow the pattern width of the photoresist. Thus, even when the photoresist is applied thinly for preventing pattern collapse, the substrate can be processed through selection of an appropriate etching gas. For example, the resist underlayer film of the present invention can be processed by using, as an etching gas, a fluorine-containing gas that achieves a significantly high etching rate for the photoresist. The organic underlayer film can be processed by using, as an etching gas, an oxygen-containing gas that achieves a significantly high etching rate for the resist underlayer film of the present invention. The substrate can be processed by using, as an etching gas, a fluorine-containing gas that achieves a significantly high etching rate for the organic underlayer film.

No particular limitation is imposed on the photoresist formed on the resist underlayer film of the present invention, so long as the photoresist is sensitive to light used for exposure. The photoresist may be either of negative and positive photoresists. Examples of the photoresist include a positive photoresist formed of a novolac resin and a 1,2-naphthoquinone diazide sulfonic acid ester; a chemically amplified photoresist formed of a binder having a group that decomposes with an acid to thereby increase an alkali dissolution rate and a photoacid generator; a chemically amplified photoresist formed of a low-molecular-weight compound that decomposes with an acid to thereby increase an alkali dissolution rate of the photoresist, an alkali-soluble binder, and a photoacid generator; and a chemically amplified photoresist formed of a binder having a group that decomposes with an acid to thereby increase an alkali dissolution rate, a low-molecular-weight compound that decomposes with an acid to thereby increase an alkali dissolution rate of the photoresist, and a photoacid generator. Specific examples of the photoresist include trade name APEX-E, available from Shipley, trade name PAR710, available from Sumitomo Chemical Company, Limited, and trade name SEPR430, available from Shin-Etsu Chemical Co., Ltd. Other examples of the photoresist include fluorine atom-containing polymer-based photoresists described in Proc. SPIE, Vol. 3999, 330-334 (2000), Proc. SPIE, Vol. 3999, 357-364 (2000), and Proc. SPIE, Vol. 3999, 365-374 (2000).

Subsequently, light exposure is performed through a predetermined mask. The light exposure may involve the use of, for example, a KrF excimer laser (wavelength: 248 nm), an ArF excimer laser (wavelength: 193 nm), and an F2 excimer laser (wavelength: 157 nm). After the light exposure, post exposure bake (PEB) may optionally be performed. The post exposure bake is performed under appropriately determined conditions; i.e., a heating temperature of 70° C. to 150° C. and a heating time of 0.3 minutes to 10 minutes.

In the present invention, a resist for electron beam lithography or a resist for EUV lithography may be used instead of the photoresist. The electron beam resist may be either of negative and positive resists. Examples of the electron beam resist include a chemically amplified resist formed of an acid generator and a binder having a group that decomposes with an acid to thereby change an alkali dissolution rate; a chemically amplified resist formed of an alkali-soluble binder, an acid generator, and a low-molecular-weight compound that decomposes with an acid to thereby change the alkali dissolution rate of the resist; a chemically amplified resist formed of an acid generator, a binder having a group that decomposes with an acid to thereby change an alkali dissolution rate, and a low-molecular-weight compound that decomposes with an acid to thereby change the alkali dissolution rate of the resist; a non-chemically amplified resist formed of a binder having a group that decomposes with electron beams to thereby change an alkali dissolution rate; and a non-chemically amplified resist formed of a binder having a moiety that is cut with electron beams to thereby change an alkali dissolution rate. Also in the case of use of such an electron beam resist, a resist pattern can be formed by using electron beams as an irradiation source in the same manner as in the case of using the photoresist.

The EUV resist may be a methacrylate resin-based resist.

Subsequently, development is performed with a developer (e.g., an alkaline developer). When, for example, a positive photoresist is used, an exposed portion of the photoresist is removed to thereby form a pattern of the photoresist.

Examples of the developer include alkaline aqueous solutions, for example, aqueous solutions of alkali metal hydroxides, such as potassium hydroxide and sodium hydroxide; aqueous solutions of quaternary ammonium hydroxides, such as tetramethylammonium hydroxide, tetraethylammonium hydroxide, and choline; and aqueous solutions of amines, such as ethanolamine, propylamine, and ethylenediamine. Such a developer may also contain, for example, a surfactant. The development is performed under appropriately determined conditions; i.e., a temperature of 5° C. to 50° C. and a time of 10 seconds to 600 seconds.

In the present invention, the developer may be an organic solvent. After the light exposure, the development is performed with a developer (a solvent). When, for example, a positive photoresist is used, an unexposed portion of the photoresist is removed to thereby form a pattern of the photoresist.

Examples of the developer include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Such a developer may also contain, for example, a surfactant. The development is performed under appropriately determined conditions; i.e., a temperature of 5° C. to 50° C. and a time of 10 seconds to 600 seconds.

The resultant patterned photoresist (upper layer) is used as a protective film for removing the resist underlayer film (intermediate layer) of the present invention. Subsequently, the patterned photoresist and the patterned resist underlayer film (intermediate layer) of the present invention are used as protective films for removing the organic underlayer film (lower layer). Finally, the patterned resist underlayer film (intermediate layer) of the present invention and the patterned organic underlayer film (lower layer) are used as protective films for processing the semiconductor substrate.

Specifically, a photoresist-removed portion of the resist underlayer film (intermediate layer) of the present invention is removed by dry etching to thereby expose the semiconductor substrate. The dry etching of the resist underlayer film of the present invention can be performed with any of gasses, such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane. The dry etching of the resist underlayer film is preferably performed with a halogen-containing gas. In general, a photoresist formed of an organic substance is hard to be removed by dry etching with a halogen-containing gas. In contrast, the resist underlayer film of the present invention, which contains numerous silicon atoms, is quickly removed by dry etching with a halogen-containing gas. Therefore, a reduction in the thickness of the photoresist in association with the dry etching of the resist underlayer film can be suppressed. Thus, the photoresist can be used in the form of thin film. The dry etching of the resist underlayer film is preferably performed with a fluorine-containing gas. Examples of the fluorine-containing gas include tetrafluoromethane (CF₄), perfluorocyclobutane (C₄F₈), perfluoropropane (C₃F₈), trifluoromethane, and difluoromethane (CH₂F₂).

Thereafter, the patterned photoresist and the patterned resist underlayer film of the present invention are used as protective films for removing the organic underlayer film. The dry etching of the organic underlayer film (lower layer) is preferably performed with an oxygen-containing gas, since the resist underlayer film of the present invention, which contains numerous silicon atoms, is less likely to be removed by dry etching with an oxygen-containing gas.

Finally, the semiconductor substrate is processed. The processing of the semiconductor substrate is preferably performed by dry etching with a fluorine-containing gas.

Examples of the fluorine-containing gas include tetrafluoromethane (CF₄), perfluorocyclobutane (C₄F₈), perfluoropropane (C₃F₈), trifluoromethane, and difluoromethane (CH₂F₂).

An organic anti-reflective coating may be formed on the resist underlayer film of the present invention before formation of the photoresist. No particular limitation is imposed on the composition used for formation of the anti-reflective coating, and the composition may be appropriately selected from anti-reflective coating compositions that have been conventionally used in a lithography process. The anti-reflective coating can be formed by a commonly used method, for example, application of the composition with a spinner or a coater, and baking of the composition.

The substrate to which the resist underlayer film-forming composition of the present invention is applied may have an organic or inorganic anti-reflective coating formed thereon by, for example, a CVD process. The resist underlayer film may be formed, on the anti-reflective coating, from the resist underlayer film-forming composition of the present invention

The resist underlayer film formed from the resist underlayer film-forming composition of the present invention may absorb light used in a lithography process depending on the wavelength of the light. In such a case, the resist underlayer film can function as an anti-reflective coating having the effect of preventing reflection of light from the substrate. Furthermore, the resist underlayer film formed from the resist underlayer film-forming composition of the present invention can be used as, for example, a layer for preventing the interaction between the substrate and the photoresist; a layer having the function of preventing the adverse effect, on the substrate, of a material used for the photoresist or a substance generated during the exposure of the photoresist to light; a layer having the function of preventing diffusion of a substance generated from the substrate during heating and baking to the photoresist serving as an upper layer; and a barrier layer for reducing a poisoning effect of a dielectric layer of the semiconductor substrate on the photoresist layer.

The resist underlayer film formed from the resist underlayer film-forming composition of the present invention can be applied to a substrate having via holes for use in a dual damascene process, and can be used as an embedding material to fill up the holes. The resist underlayer film can also be used as a planarization material for planarizing the surface of a semiconductor substrate having irregularities.

The resist underlayer film can, as an EUV resist underlayer film, not only function as a hard mask, but also be used for the purpose described below. Specifically, the resist underlayer film-forming composition can be used for an anti-reflective EUV resist underlayer coating capable of, without intermixing with an EUV resist, preventing the reflection, from a substrate or an interface, of exposure light undesirable for EUV exposure (wavelength: 13.5 nm); for example, the aforementioned UV or DUV (ArF laser light, KrF laser light). Thus, the reflection can be efficiently prevented in the underlayer of the EUV resist. When the resist underlayer film is used as an EUV resist underlayer film, the film can be processed in the same manner as in the photoresist underlayer film.

### EXAMPLES

The present invention will next be described by way of examples, but the present invention should not be construed as being limited to the examples.

### Synthesis Example 1

A 300-ml flask was charged with 25.2 g of tetraethoxysilane (70% by mole in the entire hydrolyzable silane), 7.71 g of methyltriethoxysilane (25% by mole in the entire hydrolyzable silane), 2.48 g of ethoxyethoxyphenyltrimethoxysilane (5% by mole in the entire hydrolyzable silane), and 53.1 g of acetone. While the resultant mixture was stirred with a magnetic stirrer, 11.5 g of 0.01 M aqueous nitric acid solution was added dropwise to the mixture. After completion of the dropwise addition, the flask was transferred to an oil bath set at 85° C., and the mixture was refluxed for 240 minutes. Thereafter, 70 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether acetate was added to the aqueous solution so as to achieve a solvent proportion of propylene glycol monomethyl ether acetate of 100% and a solid residue content of 20% by weight at 140° C. The resultant polymer (corresponding to Formula (3-1)) was then converted into a mixture of the polymers corresponding to Formulae (3-1) and (4-1). The polymer mixture was found to have a weight average molecular weight (Mw) of 3,000 as determined by GPC in terms of polystyrene.

### Synthesis Example 2

A 300-ml flask was charged with 22.6 g of tetraethoxysilane (70% by mole in the entire hydrolyzable silane), 13.3 g of ethoxyethoxyphenyltrimethoxysilane (30% by mole in the entire hydrolyzable silane), and 53.8 g of acetone. While the resultant mixture was stirred with a magnetic stirrer, 10.3 g of 0.01 M aqueous nitric acid solution was added dropwise to the mixture. After completion of the dropwise addition, the flask was transferred to an oil bath set at 85° C., and the mixture was refluxed for 240 minutes. Thereafter, 70 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether acetate was added to the aqueous solution so as to achieve a solvent proportion of propylene glycol monomethyl ether acetate of 100% and a solid residue content of 20% by weight at 140° C. The resultant polymer (corresponding to Formula (3-2)) was then converted into a mixture of the polymers corresponding to Formulae (3-2) and (4-2). The polymer mixture was found to have a weight average molecular weight (Mw) of 2,700 as determined by GPC in terms of polystyrene.

### Synthesis Example 3

A 300-ml flask was charged with 25.5 g of tetraethoxysilane (70% by mole in the entire hydrolyzable silane), 7.80 g of methyltriethoxysilane (25% by mole in the entire hydrolyzable silane), 2.00 g of methoxyphenyltrimethoxysilane (5% by mole in the entire hydrolyzable silane), and 53.0 g of acetone. While the resultant mixture was stirred with a magnetic stirrer, 11.7 g of 0.1 M aqueous nitric acid solution was added dropwise to the mixture. After completion of the dropwise addition, the flask was transferred to an oil bath set at 85° C., and the mixture was refluxed for 240 minutes. Thereafter, 70 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether acetate was added to the aqueous solution so as to achieve a solvent proportion of propylene glycol monomethyl ether acetate of 100% and a solid residue content of 20% by weight at 140° C. The resultant polymer (corresponding to Formula (3-3)) was then converted into a mixture of the polymers corresponding to Formulae (3-3) and (4-1). The polymer mixture was found to have a weight average molecular weight (Mw) of 2,800 as determined by GPC in terms of polystyrene.

### Synthesis Example 4

A 300-ml flask was charged with 24.2 g of tetraethoxysilane (70% by mole in the entire hydrolyzable silane), 11.37 g of methoxyphenyltrimethoxysilane (30% by mole in the entire hydrolyzable silane), and 53.4 g of acetone. While the resultant mixture was stirred with a magnetic stirrer, 11.1 g of 0.01 M aqueous nitric acid solution was added dropwise to the mixture. After completion of the dropwise addition, the flask was transferred to an oil bath set at 85° C., and the mixture was refluxed for 240 minutes. Thereafter, 70 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether acetate was added to the aqueous solution so as to achieve a solvent proportion of propylene glycol monomethyl ether acetate of 100% and a solid residue content of 20% by weight at 140° C. The resultant polymer (corresponding to Formula (3-4)) was then converted into a mixture of the polymers corresponding to Formulae (3-4) and (4-2). The polymer mixture was found to have a weight average molecular weight (Mw) of 2,200 as determined by GPC in terms of polystyrene.

### Synthesis Example 5

A 300-ml flask was charged with 25.5 g of tetraethoxysilane (70% by mole in the entire hydrolyzable silane), 7.78 g of methyltriethoxysilane (25% by mole in the entire hydrolyzable silane), 2.11 g of methoxybenzyltrimethoxysilane (5% by mole in the entire hydrolyzable silane), and 53.0 g of acetone. While the resultant mixture was stirred with a magnetic stirrer, 11.6 g of 0.01 M aqueous nitric acid solution was added dropwise to the mixture. After completion of the dropwise addition, the flask was transferred to an oil bath set at 85° C., and the mixture was refluxed for 240 minutes. Thereafter, 70 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether acetate was added to the aqueous solution so as to achieve a solvent proportion of propylene glycol monomethyl ether acetate of 100% and a solid residue content of 20% by weight at 140° C. The resultant polymer (corresponding to Formula (3-5)) was then converted into a mixture of the polymers corresponding to Formulae (3-5) and (4-3). The polymer mixture was found to have a weight average molecular weight (Mw) of 2,400 as determined by GPC in terms of polystyrene.

### Synthesis Example 6

A 300-ml flask was charged with 23.8 g of tetraethoxysilane (70% by mole in the entire hydrolyzable silane), 11.9 g of methoxybenzyltrimethoxysilane (30% by mole in the entire hydrolyzable silane), and 53.5 g of acetone. While the resultant mixture was stirred with a magnetic stirrer, 10.8 g of 1 M aqueous nitric acid solution was added dropwise to the mixture. After completion of the dropwise addition, the flask was transferred to an oil bath set at 85° C., and the mixture was refluxed for 240 minutes. Thereafter, 70 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether acetate was added to the aqueous solution so as to achieve a solvent proportion of propylene glycol monomethyl ether acetate of 100% and a solid residue content of 20% by weight at 140° C. The resultant polymer (corresponding to Formula (3-6)) was then converted into a mixture of the polymers corresponding to Formulae (3-6) and (4-4). The polymer mixture was found to have a weight average molecular weight (Mw) of 3,500 as determined by GPC in terms of polystyrene.

### Synthesis Example 7

A 300-ml flask was charged with 24.9 g of tetraethoxysilane (70% by mole in the entire hydrolyzable silane), 7.61 g of methyltriethoxysilane (25% by mole in the entire hydrolyzable silane), 2.94 g of triethoxy((2-methoxy-4-(methoxymethyl)phenoxy)methyl)silane (5% by mole in the entire hydrolyzable silane), and 53.2 g of acetone. While the resultant mixture was stirred with a magnetic stirrer, 11.4 g of 0.01 M aqueous nitric acid solution was added dropwise to the mixture. After completion of the dropwise addition, the flask was transferred to an oil bath set at 85° C., and the mixture was refluxed for 240 minutes. Thereafter, 70 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether acetate was added to the aqueous solution so as to achieve a solvent proportion of propylene glycol monomethyl ether acetate of 100% and a solid residue content of 20% by weight at 140° C. The resultant polymer (corresponding to Formula (3-7)) was then converted into a mixture of the polymers corresponding to Formulae (3-7), (4-5), and (4-7). The polymer mixture was found to have a weight average molecular weight (Mw) of 2,800 as determined by GPC in terms of polystyrene.

### Synthesis Example 8

A 300-ml flask was charged with 21.1 g of tetraethoxysilane (70% by mole in the entire hydrolyzable silane), 14.99 g of triethoxy((2-methoxy-4-(methoxymethyl)phenoxy)methyl)silane (30% by mole in the entire hydrolyzable silane), and 54.2 g of acetone. While the resultant mixture was stirred with a magnetic stirrer, 9.67 g of 0.01 M aqueous nitric acid solution was added dropwise to the mixture. After completion of the dropwise addition, the flask was transferred to an oil bath set at 85° C., and the mixture was refluxed for 240 minutes. Thereafter, 70 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether acetate was added to the aqueous solution so as to achieve a solvent proportion of propylene glycol monomethyl ether acetate of 100% and a solid residue content of 20% by weight at 140° C. The resultant polymer (corresponding to Formula (3-8)) was then converted into a mixture of the polymers corresponding to Formulae (3-8), (4-6), and (4-8). The polymer mixture was found to have a weight average molecular weight (Mw) of 2,500 as determined by GPC in terms of polystyrene.

### Comparative Synthesis Example 1

A 300-ml flask was charged with 25.8 g of tetraethoxysilane, 9.5 g of triethoxymethylsilane, and 52.9 g of acetone. While the resultant mixture was stirred with a magnetic stirrer, 11.8 g of 0.01 M aqueous hydrochloric acid solution was added dropwise to the mixture. After completion of the dropwise addition, the flask was transferred to an oil bath set at 85° C., and the mixture was refluxed for 240 minutes. Thereafter, 70 g of propylene glycol monomethyl ether acetate was added to the mixture, and then acetone, methanol, ethanol, and water were distilled off under reduced pressure, followed by concentration, to thereby prepare an aqueous solution of a hydrolysis condensate (polymer). Subsequently, propylene glycol monomethyl ether acetate was added to the aqueous solution so as to achieve a solid residue content of 20% by weight at 140° C. The resultant polymer (corresponding to Formula (5-1)) was found to have a weight average molecular weight (Mw) of 1,800 as determined by GPC in terms of polystyrene.

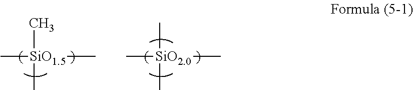

### Comparative Synthesis Example 2

A 300-ml flask was charged with 25.8 g of tetraethoxysilane, 9.5 g of triethoxymethylsilane, and 52.9 g of acetone. While the resultant mixture was stirred with a magnetic stirrer, 11.8 g of 11 M aqueous nitric acid solution was added dropwise to the mixture. After completion of the dropwise addition, the flask was transferred to an oil bath set at 85° C. Acetone was then added to the mixture for concentration adjustment, and the mixture was refluxed for 240 minutes. Thereafter, a white precipitate was generated, and a target polymer failed to be prepared.

The resultant polymer solution was found to contain nitric acid ions in an amount of 10,000 ppm.

[Post-Filtration Stability of Synthesized Polymer]

Each of the polysiloxanes (polymers) prepared in the aforementioned Synthesis Examples was filtered with a nylon filter having a pore size of 10 nm, and a change in the molecular weight of the polymer between before and after filtration was determined on the basis of a change in GPC spectra. A polymer exhibiting a change in molecular weight of 10% or less was evaluated as “Good,” whereas a polymer exhibiting a change in molecular weight of 10% or more was evaluated as “Not good.” The results are shown in Table 1.

TABLE 1
Change in molecular weight between
before and after filtration with nylon filter

| | |
|---|---|
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Comparative Example 1 | Not good |
| Comparative Example 2 | Not good |

[Preparation of Resist Underlayer Film-Forming Composition]

Each of the polysiloxanes (polymers) prepared in the aforementioned Synthesis Examples, an acid, and a solvent were mixed in proportions shown in Table 1, and the resultant mixture was filtered with a polyethylene-made filter (0.1 μm), to thereby prepare a composition to be applied to a resist pattern. The amount of each polymer shown in Table 1 corresponds not to the amount of the polymer solution, but to the amount of the polymer itself.

In Table 2, “Water” denotes ultrapure water. The amount of each component is represented by “part(s) by mass.” In Table 2, MA denotes maleic acid; TPSNO3, triphenylsulfonium nitrate; TPSTFA, triphenylsulfonium trifluoroacetate; TPSML, triphenylsulfonium maleate; TPSCl, triphenylsulfonium chloride; BTEAC, benzyltriethylammonium chloride; TMANO3, tetramethylammonium nitrate; TPSCS, triphenylsulfonium camphorsulfonate; TPSAdTf, triphenylsulfonium butyl adamantanecarboxylate trifluoromethanesulfonate; PGEE, propylene glycol monoethyl ether; PGMEA, propylene glycol monomethyl ether acetate; and PGME, propylene glycol monomethyl ether.

TABLE 2

| | Si polymer | | | | | | | |
|---|---|---|---|---|---|---|---|---|
| Composition | solution | Additive 1 | Additive 2 | | Solvent | | | |
| Example 1 | Synthesis | MA | TPSNO3 | | PGEE | PGMEA | PGME | Water |
| (part(s) by mass) | Example 1 | 0.03 | 0.03 | | 70 | 10 | 8 | 12 |
| | 1 | | | | | | | |
| Example 2 | Synthesis | MA | TPSTFA | | PGEE | PGMEA | PGME | Water |
| (part(s) by mass) | Example 2 | 0.03 | 0.03 | | 70 | 10 | 8 | 12 |
| | 1 | | | | | | | |
| Example 3 | Synthesis | MA | TPSML | | PGEE | PGMEA | PGME | Water |
| (part(s) by mass) | Example 3 | 0.03 | 0.03 | | 70 | 10 | 8 | 12 |
| | 1 | | | | | | | |
| Example 4 | Synthesis | MA | TPSC1 | | PGEE | PGMEA | PGME | Water |
| (part(s) by mass) | Example 4 | 0.03 | 0.03 | | 70 | 10 | 8 | 12 |
| | 1 | | | | | | | |
| Example 5 | Synthesis | MA | BTEAC | | PGEE | PGMEA | PGME | Water |
| (part(s) by mass) | Example 5 | 0.03 | 0.03 | | 70 | 10 | 8 | 12 |
| | 1 | | | | | | | |
| Example 6 | Synthesis | MA | TMANO3 | | PGEE | PGMEA | PGME | Water |
| (part(s) by mass) | Example 6 | 0.03 | 0.03 | | 70 | 10 | 8 | 12 |
| | 1 | | | | | | | |
| Example 7 | Synthesis | MA | TPSNO3 | TPSCS | PGEE | PGMEA | PGME | Water |
| (part(s) by mass) | Example 7 | 0.03 | 0.03 | 0.05 | 70 | 10 | 8 | 12 |
| | 1 | | | | | | | |
| Example 8 | Synthesis | MA | TPSTFA | TPSAdTf | PGEE | PGMEA | PGME | Water |
| (part(s) by mass) | Example 8 | 0.03 | 0.03 | 0.05 | 70 | 10 | 8 | 12 |
| | 1 | | | | | | | |

| | | | | | | | |
|---|---|---|---|---|---|---|---|
| Comparative | Comparative | MA | | PGEE | PGMEA | PGME | Water |
| Example 1 | Synthesis | 0.03 | | 70 | 10 | 8 | 12 |
| (part(s) by mass) | Example 1 | | | | | | |
| | 1 | | | | | | |
| Comparative | Comparative | MA | TMANO3 | PGEE | PGMEA | PGME | Water |
| Example 2 | Synthesis | 0.03 | 0.05 | 70 | 10 | 8 | 12 |
| (part(s) by mass) | Example 1 | | | | | | |
| | 1 | | | | | | |

TABLE 3
Nitric acid ion content (ppm)

| | |
|---|---|
| Example 1 | 5 ppm |
| Example 2 | 5 ppm |
| Example 3 | 50 ppm |
| Example 4 | 5 ppm |
| Example 5 | 5 ppm |
| Example 6 | 500 ppm |
| Example 7 | 5 ppm |
| Example 8 | 5 ppm |
| Comparative Example 1 | 0 ppm |
| Comparative Example 2 | 0 ppm |

[Preparation of Organic Underlayer Film (Layer A)-Forming Composition]

In a nitrogen atmosphere, a 100-ml four-necked flask was charged with 6.69 g (0.040 mol) of carbazole (available from Tokyo Chemical Industry Co., Ltd.), 7.28 g (0.040 mol) of 9-fluorenone (available from Tokyo Chemical Industry Co., Ltd.), 0.76 g (0.0040 mol) of p-toluenesulfonic acid monohydrate (available from Tokyo Chemical Industry Co., Ltd.), and 6.69 g of 1,4-dioxane (available from Kanto Chemical Co., Inc.), and the resultant mixture was stirred. The mixture was heated to 100° C. for dissolution, to thereby initiate polymerization. After the elapse of 24 hours, the mixture was left to cool to 60° C. The mixture was then diluted with 34 g of chloroform (available from Kanto Chemical Co., Inc.) and reprecipitated in 168 g of methanol (available from Kanto Chemical Co., Inc.). The resultant precipitate was filtered and dried with a reduced pressure dryer at 80° C. for 24 hours, to thereby yield 9.37 g of a target polymer (Formula (3-1), hereinafter abbreviated as “PCzFL”).

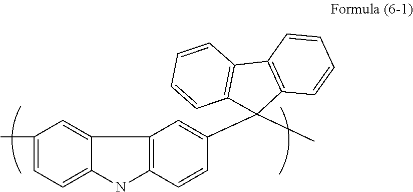

The results of ¹H-NMR analysis of PCzFL were as follows: ¹H-NMR (400 MHz, DMSO-d₆): δ7.03-7.55 (br, 12H), δ7.61-8.10 (br, 4H), δ11.18 (br, 1H).

PCzFL was found to have a weight average molecular weight (Mw) of 2,800 as determined by GPC in terms of polystyrene and a polydispersity Mw (weight average molecular weight)/Mn (number average molecular weight) of 1.77.

Subsequently, 20 g of the resultant resin was mixed with 3.0 g of tetramethoxymethyl glycoluril (trade name: Powderlink 1174, available from Mitsui Cytec Ltd.) serving as a crosslinking agent, 0.30 g of pyridinium p-toluenesulfonate serving as a catalyst, and 0.06 g of MEGAFAC R-30 (trade name, available from DIC Corporation) serving as a surfactant, and the mixture was dissolved in 88 g of propylene glycol monomethyl ether acetate, to thereby prepare a solution. Thereafter, the solution was filtered with a polyethylene-made microfilter (pore size: 0.10 μm), and then filtered with a polyethylene-made microfilter (pore size: 0.05 μm), to thereby prepare a solution of an organic underlayer film (layer A)-forming composition used for a lithography process using a multilayer film.

[Solvent Resistance Test]

Each of the resist underlayer film-forming compositions prepared in Examples 1 to 8 and Comparative Examples 1 and 2 was applied onto a silicon wafer with a spinner, and then heated on a hot plate at 215° C. for one minute, to thereby form a resist underlayer film. Thereafter, a solvent of propylene glycol monomethyl ether/propylene glycol monomethyl ether acetate (=7/3, mass ratio) was applied onto the resist underlayer film and then spin-dried for determining a change in film thickness between before and after application of the solvent. Solvent resistance was evaluated as “Good” when a change in film thickness was 1% or less, or evaluated as “Not cured” when a change in film thickness was 1% or more. The results are shown in Table 4.

[Developer Solubility Test]

Each of the resist underlayer film-forming compositions prepared in Examples 1 to 8 and Comparative Examples 1 and 2 was applied onto a silicon wafer with a spinner, and then heated on a hot plate at 215° C. for one minute, to thereby form a resist underlayer film. Thereafter, an alkaline developer (2.38% aqueous TMAH solution (TMAH denotes tetramethylammonium hydroxide)) was applied onto the resist underlayer film and then spin-dried for determining a change in film thickness between before and after application of the solvent. Developer resistance was evaluated as “Good” when a change in film thickness was 1% or less, or evaluated as “Not cured” when a change in film thickness was 1% or more. The results are shown in Table 4.

TABLE 4

| | Solvent resistance | Developer resistance |
|---|---|---|
| Example 1 | Good | Good |
| Example 2 | Good | Good |
| Example 3 | Good | Good |
| Example 4 | Good | Good |
| Example 5 | Good | Good |
| Example 6 | Good | Good |
| Example 7 | Good | Good |
| Example 8 | Good | Good |
| Comparative Example 1 | Not cured | Not cured |
| Comparative Example 2 | Good | Good |

[Formation of Resist Pattern by EUV Exposure: Positive Alkali Development]

The aforementioned organic underlayer film (layer A)-forming composition was applied onto a silicon wafer, and then baked on a hot plate at 215° C. for 60 seconds, to thereby form an organic underlayer film (layer A) having a thickness of 90 nm. Each of the resist underlayer film-forming composition solutions prepared in Examples 1 to 8 and Comparative Example 2 was applied onto layer A by spin coating, and then heated at 215° C. for one minute, to thereby form a resist underlayer film (layer B) (20 nm). An EUV resist solution (methacrylate resin resist) was applied onto the resist underlayer film (hard mask) by spin coating, and then heated to form an EUV resist layer (layer C). The EUV resist layer was exposed to light with an EUV exposure apparatus (NXE3300B, available from ASML) under the following conditions: NA: 0.33, 6: 0.67/0.90, cQuad. After the light exposure, PEB was performed, and the resultant product was cooled on a cooling plate to room temperature, followed by development with an alkaline developer (2.38% aqueous TMAH solution) for 60 seconds and rinsing treatment, to thereby form a resist pattern. The resist pattern was evaluated for formation of a 20 nm hole with a 40 nm pitch. The pattern shape was evaluated by observation of a cross section of the pattern. The results are shown in Table 5.

In Table 5, “Good” indicates a shape between footing and undercut and a state of no significant residue in a space portion; “Collapse” indicates an unfavorable state of peeling and collapse of the resist pattern; and “Bridge” indicates an unfavorable state of contact between upper portions or lower portions of the resist pattern.

TABLE 5

| | Pattern shape |
|---|---|
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Comparative Example 2 | Not good (Bridge) |

[Formation of Resist Pattern by EUV Exposure: Negative Solvent Development]

The aforementioned organic underlayer film (layer A)-forming composition was applied onto a silicon wafer, and then baked on a hot plate at 215° C. for 60 seconds, to thereby form an organic underlayer film (layer A) having a thickness of 90 nm. Each of the resist underlayer film-forming composition solutions prepared in Examples 1 to 8 and Comparative Example 2 was applied onto layer A by spin coating, and then heated at 215° C. for one minute, to thereby form a resist underlayer film (layer B) (20 nm). An EUV resist solution (methacrylate resin resist) was applied onto the resist underlayer film (hard mask) by spin coating, and then heated to form an EUV resist layer (layer C). The EUV resist layer was exposed to light with an EUV exposure apparatus (NXE3300B, available from ASML) under the following conditions: NA: 0.33, 6: 0.67/0.90, Dipole. After the light exposure, PEB was performed, and the resultant product was cooled on a cooling plate to room temperature, followed by development with an organic solvent developer (butyl acetate) for 60 seconds and rinsing treatment, to thereby form a resist pattern. The resist pattern was evaluated for formation of a 20 nm line and space. The pattern shape was evaluated by observation of a cross section of the pattern. The results are shown in Table 6.

In Table 6, “Good” indicates a shape between footing and undercut and a state of no significant residue in a space portion; “Collapse” indicates an unfavorable state of peeling and collapse of the resist pattern; and “Bridge” indicates an unfavorable state of contact between upper portions or lower portions of the resist pattern.

TABLE 6

| | Pattern shape |
|---|---|
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Comparative Example 2 | Not good (Collapse) |

### INDUSTRIAL APPLICABILITY

The present invention can provide a resist underlayer film-forming composition for lithography that can be used in the production of a semiconductor device; specifically, a resist underlayer film-forming composition for lithography for forming a resist underlayer film that can be used as a hard mask.

1. A resist underlayer film-forming composition for lithography comprising a hydrolysis condensate (c) of a hydrolyzable silane (a) as a silane, nitric acid ions, and a solvent, wherein the hydrolyzable silane (a) contains a hydrolyzable silane of the following Formula (1):
R¹ₐR²_{b}Si(R³)_{4-(a+b)} Formula (1)
[wherein R¹ is an organic group of the following Formula (2): 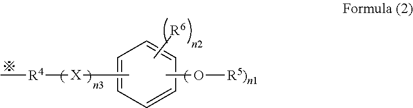
(wherein X is an oxygen atom, a sulfur atom, or a nitrogen atom; R⁴ is a single bond or a C₁₋₁₀ alkylene group; R⁵ is a C₁₋₁₀ alkyl group optionally containing a C₁₋₁₀ alkoxy group; R⁶ is a C₁₋₁₀ alkyl group; each of n1 and n2 satisfies 1≤n1≤5 and 0≤n2≤(5−n1); n3 is 0 or 1; and ※ is a site of bonding to a silicon atom) and is bonded to a silicon atom via an Si—C bond; R² is an alkyl group, an aryl group, a halogenated alkyl group, a halogenated aryl group, an alkoxyaryl group, an alkenyl group, or an organic group having an epoxy group, an acryloyl group, a methacryloyl group, a mercapto group, an amino group, or a cyano group, and is bonded to a silicon atom via an Si—C bond; R³ is an alkoxy group, an acyloxy group, or a halogen group; a is an integer of 1; b is an integer of 0 to 2; and a+b is an integer of 1 to 3].

2. The resist underlayer film-forming composition according to claim 1, wherein the composition further comprises the hydrolyzable silane (a) and/or a hydrolysate (b) thereof.

3. The resist underlayer film-forming composition according to claim 1, wherein the amount of the nitric acid ions contained in the composition falls within a range of 1 ppm to 1,000 ppm.

4. The resist underlayer film-forming composition according to claim 1, wherein, in the hydrolysis condensate (c), the functional group of Formula (2) in the hydrolyzable silane of Formula (1) satisfies a (hydrogen atom)/(hydrogen atom+R⁵ group) ratio by mole of 1% to 100%.

5. The resist underlayer film-forming composition according to claim 1, wherein the hydrolyzable silane (a) is a combination of the hydrolyzable silane of Formula (1) and an additional hydrolyzable silane, and the additional hydrolyzable silane is at least one hydrolyzable silane selected from the group consisting of hydrolyzable silanes of the following Formula (3):
R⁷_{c}Si(R⁸)_{4-c} Formula (3)
(wherein R⁷ is an alkyl group, an aryl group, a halogenated alkyl group, a halogenated aryl group, an alkoxyaryl group, an alkenyl group, or an organic group having an epoxy group, an acryloyl group, a methacryloyl group, a mercapto group, or a cyano group, and is bonded to a silicon atom via an Si—C bond; R⁸ is an alkoxy group, an acyloxy group, or a halogen atom; and c is an integer of 0 to 3) and the following Formula (4):
[R⁹_{d}Si(R¹⁰)_{3-d}]₂Yₑ Formula (4)
(wherein R⁹ is an alkyl group and is bonded to a silicon atom via an Si—C bond; R¹⁰ is an alkoxy group, an acyloxy group, or a halogen group; Y is an alkylene group or an arylene group; d is an integer of 0 or 1; and e is an integer of 0 or 1).

6. The resist underlayer film-forming composition according to claim 5, wherein the composition comprises, as a polymer, a hydrolysis condensate of a hydrolyzable silane containing a combination of the hydrolyzable silane of Formula (1) and the hydrolyzable silane of Formula (3).

7. The resist underlayer film-forming composition according to claim 1, wherein the composition further comprises an additive selected from water, an acid, a photoacid generator, a surfactant, a metal oxide, or any combination of these.

8. A method for producing the resist underlayer film-forming composition according to claim 1, the method comprising a step (A) of filtering, with a filter comprising a polar group-containing filter, a polymer solution containing the hydrolysis condensate (c) of the hydrolyzable silane, or the hydrolysis condensate (c) of the hydrolyzable silane and the hydrolyzable silane (a) and/or the hydrolysate (b) thereof, and nitric acid ions, and a solvent.

9. The method for producing the resist underlayer film-forming composition according to claim 8, wherein the polar group-containing filter is a nylon filter.

10. The method for producing the resist underlayer film-forming composition according to claim 8, wherein the method further comprises a step (B) of filtering, with a filter, a solution prepared by addition of the additive selected from water, an acid, a photoacid generator, a surfactant, a metal oxide, or any combination of these to the polymer solution.

11. A method for producing a semiconductor device, the method comprising a step of applying, onto a semiconductor substrate, the resist underlayer film-forming composition according to claim 1, followed by baking the composition, to thereby form a resist underlayer film; a step of applying a resist composition onto the underlayer film to thereby form a resist layer; a step of exposing the resist layer to light; a step of developing the resist layer after the light exposure to thereby form a resist pattern; a step of etching the resist underlayer film with the resist pattern; and a step of processing the semiconductor substrate with the patterned resist layer and resist underlayer film.

12. A method for producing a semiconductor device, the method comprising a step of forming an organic underlayer film on a semiconductor substrate; a step of applying, onto the organic underlayer film, the resist underlayer film-forming composition according to claim 1 followed by baking the composition, to thereby form a resist underlayer film; a step of applying a resist composition onto the resist underlayer film to thereby form a resist layer; a step of exposing the resist layer to light; a step of developing the resist layer after the light exposure to thereby form a resist pattern; a step of etching the resist underlayer film with the resist pattern; a step of etching the organic underlayer film with the patterned resist underlayer film; and a step of processing the semiconductor substrate with the patterned organic underlayer film.
